(19) United States
(12) Patent Application Publication
(10) Pub. No.: US 2018/0340033 A1
(43) Pub. Date: Nov. 29, 2018

(54) POLYMERIC ADDITIVES FOR MORPHOLOGICALLY STABLE ORGANIC LIGHT EMITTING DIODE AND METHODS OF MANUFACTURE THEREOF

(71) Applicants: The Penn State Research Foundation, University Park, PA (US); Dow Global Technologies LLC, Midland, MI (US)

(72) Inventors: Jared Scott Price, Woodbridge, VA (US); Noel Christopher Giebink, State College, PA (US); Anatoliy N. Sokolov, Midland, MI (US); Sukrit Mukhopadhyay, Midland, MI (US)

(21) Appl. No.: 15/988,473

(22) Filed: May 24, 2018

Related U.S. Application Data
(60) Provisional application No. 62/510,518, filed on May 24, 2017.

(51) Int. Cl. C08F 14/18; C08F 2/34; C08F 8/50; C08L 27/22; C08K 5/3437; C08K 5/18; H01L 51/00

(52) U.S. Cl. CPC C08F 14/18; C08F 2/34; C08F 8/50; C08L 27/22; H01L 51/5056; C08K 5/18; H01L 51/004; C08K 2201/001; C08L 2205/04; C08K 5/3437

(57) ABSTRACT

Disclosed herein is a composition comprising a co-continuous interpenetrating network of an organic polymer and a electroactive moiety; where the organic polymer is operative to depolymerize at a temperature of 50 to 500° C. and to repolymerize on a surface in the presence of the electroactive moiety; and where the electroactive moiety is an organic semiconductor that does not react with a repolymerized polymer. Disclosed herein too is a method comprising co-evaporating a polymeric precursor and an electroactive moiety onto a substrate; condensing the polymeric precursor and an electroactive moiety on the substrate; and polymerizing the polymeric precursor to form a co-continuous interpenetrating network of an organic polymer and an electroactive moiety; where the electroactive moiety is defined as a chemical functional group which is capable of transporting an electrical charge.

### CROSS REFERENCE TO RELATED APPLICATIONS

This application is a Non-Provisional application which claims the benefit of U.S. Provisional Application No. 62/510,518, filed May 24, 2017, which is incorporated by reference in its entirety herein.

### BACKGROUND

Display devices have become an integral part of society as a means of information transfer. In particular, organic light emitting diode (OLED) displays are among the most energy efficient 2D display technologies and can be found in everyday appliances, including smartphones, laptops, and televisions. Two aspects that have made efficient OLED displays possible are the use of phosphorescent materials and multi-colored pixel arrays. However, the energy efficiency of OLED displays is offset by the cost of production, in part, due to the use of evaporative deposition processes.

One of the drawbacks of OLEDs as they continue to expand in the commercial marketplace is their inability to withstand high temperature operations and high temperature storage conditions. High temperature stability of OLEDs (during operation and storage) is desirable not only because intrinsic OLED lifetime depends inversely on temperature, but also because high thermal stability is important for new applications such as automotive lighting, where interior car temperatures often exceed the ambient by 50° C. or more.

It is therefore desirable to increase the temperature stability of OLEDS while not reducing their light output and while not increasing the cost of manufacturing.

### SUMMARY

Disclosed herein is a composition comprising a co-continuous interpenetrating network of an organic polymer and a electroactive moiety; where the organic polymer is operative to depolymerize at a temperature of 50 to 500° C. and to repolymerize on a surface in the presence of the electroactive moiety; and where the electroactive moiety is an organic semiconductor that does not react with a repolymerized polymer.

Disclosed herein too is a method comprising co-evaporating a polymeric precursor and an electroactive moiety onto a substrate; condensing the polymeric precursor and an electroactive moiety on the substrate; and polymerizing the polymeric precursor to form a co-continuous interpenetrating network of an organic polymer and an electroactive moiety; where the electroactive moiety is defined as a chemical functional group which is capable of transporting an electrical charge.

### BRIEF DESCRIPTION OF THE FIGURES

FIG. 1 depicts one exemplary embodiment of a display that contains the composition disclosed herein;

FIG. 2A displays the current density-voltage (J-V) characteristics of the neat TAPC;

FIG. 2B displays the current density-voltage (J-V) characteristics of TEFLON:TAPC devices at various temperatures on a hot plate;

FIG. 2C shows a table that summarizes the key comparison points between the two device types;

FIG. 3A displays the J-V characteristics measured for the devices of Example 2;

FIG. 3B displays the external quantum efficiency (EQE) for the devices of Example 2;

FIG. 3C shows a table that summarizes the key comparison points between the neat and TEFLON-blended devices;

FIG. 3D shows photographs of the luminescence of a device that comprises the neat electroactive moiety and another device that comprises the TEFLON-electroactive moiety at different temperatures; it can be seen that the device that comprises the TEFLON-electroactive moiety is capable of luminescing at higher temperatures that the device that contain the neat electroactive moiety;

FIG. 4A shows the improved morphological stability of TEFLON-blended OLED materials stored over extended time periods;

FIG. 4B shows the increased contact angle for TEFLON:NPD blends as compared with neat NPD;

FIG. 4C shows the decrease in refractive index for TEFLON:NPD blends as compared with neat NPD;

FIG. 5A depicts the test structure for the control sample that contains only the electroactive moiety;

FIG. 5B depicts the test structure for a sample that contains the electroactive moiety and the polymer;

FIG. 5C is a graph that shows the refractive index for the a) pure NPD, b) the NPD/TEFLON AF composition, c) the pure TEFLON AF and d) the TEFLON AF sample after removing the NPD; and

FIG. 5D is a photomicrograph that shows the pure NPD sample and d) the NPD/TEFLON AF sample.

### DETAILED DESCRIPTION

Disclosed herein is a composition that comprises a porous polymer and an electroactive moiety (that is used in an organic light emitting diode), where the electroactive moiety forms a co-continuous phase with the porous polymer. Put another way, the composition comprises an interpenetrating network of the polymer and the electroactive moiety. Disclosed herein too is an article comprising the aforementioned composition.

Disclosed herein too is a method of manufacturing the composition comprising co-evaporating a precursor to the porous polymer and the electroactive moiety onto a substrate. In an embodiment, the porous polymer that forms the co-continuous phase with the electroactive moiety is evaporated from an existing polymer that is depolymerized at an elevated temperature and repolymerizes as it contacts the substrate along with the vapors of the electroactive moiety. In another embodiment, the porous polymer that forms the co-continuous phase with the electroactive moiety is directly polymerized from a monomer using gas phase polymerization. The polymer is disposed on the substrate using gas phase polymerization while the electroactive moiety is also simultaneously being condensed on the substrate. The co-condensation of the monomers and the electroactive moieties on the substrate result in the formation of a polymer that interpenetrates with the electroactive moiety. This interpenetrating network results in an increased stability for the electroactive moiety thus resulting in the production of OLEDs that have higher operating, processing and storage temperatures.

The organic polymer is preferably one that depolymerizes but preferably does not undergo decomposition or degradation upon being heated. While it is desirable for the depolymerized polymer to avoid degradation, some degradation or decomposition may occur during heating. This degradation upon heating is preferably less than 20 wt %, preferably less than 10 wt %, more preferably less than 5 wt % and more preferably less than 2 wt %, based on the total weight of the organic polymer prior to being heated.

The organic polymer then repolymerizes when disposed on a substrate. It can repolymerize in the presence of and upon contact with the electroactive moiety to form an interpenetrating network with the electroactive moiety. In an embodiment, the repolymerization occurs without undergoing a reaction with the electroactive moiety. In other words, no covalent or ionic bonds are formed with the electroactive moiety upon undergoing repolymerization.

In an embodiment, the depolymerization and repolymerization occurs at a temperature of 50 to 500° C., preferably 80 to 400° C., preferably 100 to 300° C. The depolymerization and repolymerization is preferably conducted in a vacuum. In an embodiment, the depolymerization and repolymerization occurs in a vacuum of less than 760 Torr to 10⁻⁵ Torr. In an embodiment, the composition comprises a co-continuous interpenetrating network of a fluorinated polymer and a non-fluorinated electroactive moiety, where the electroactive moiety is defined as a chemical functional group which is capable of transporting an electrical charge and emitting light upon activation by the electrical charge.

In an embodiment, the composition may comprise less than 50 mol percent of fluorine.

The polymer used in the composition is an organic polymer. Organic polymers used in the composition may be selected from a wide variety of thermoplastic polymers, blend of thermoplastic polymers, thermosetting polymers, or blends of thermoplastic polymers with thermosetting polymers. The organic polymer may also be a blend of polymers, copolymers, terpolymers, or combinations comprising at least one of the foregoing organic polymers. The organic polymer can also be an oligomer, a homopolymer, a copolymer, a block copolymer, an alternating block copolymer, a random polymer, a random copolymer, a random block copolymer, a graft copolymer, a star block copolymer, a dendrimer, a polyelectrolyte (polymers that have some repeat groups that contain electrolytes), a polyampholyte (a polyelectrolyte having both cationic and anionic repeat groups), an ionomer, or the like, or a combination comprising at last one of the foregoing organic polymers. The organic polymers have number average molecular weights greater than 2,000 grams per mole, preferably greater than 20,000 g/mole and more preferably greater than 50,000 g/mole. The polymer preferably has a glass transition temperature of greater than 50° C., preferably greater than 75° C., and more preferably greater than 100° C. It is also desirable that the polymer not act as a trap for the desired charge carrier.

Examples of the organic polymers are polyacetals, polyolefins, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyphthalides, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polyethylene terephthalate, polybutylene terephthalate, polyurethane, polytetrafluoroethylene, perfluoroelastomers, fluorinated ethylene propylene, perfluoroalkoxyethylene, polychlorotrifluoroethylene, polyvinylidene fluoride, polysiloxanes, amorphous fluoropolymers, or the like, or a combination comprising at least one of the foregoing organic polymers.

Examples of polyelectrolytes are polystyrene sulfonic acid, polyacrylic acid, pectin, carrageenan, alginates, carboxymethylcellulose, polyvinylpyrrolidone, or the like, or a combination comprising at least one of the foregoing polyelectrolytes.

Examples of thermosetting polymers suitable for use as hosts in emissive layer include epoxy polymers, unsaturated polyester polymers, polyimide polymers, bismaleimide polymers, bismaleimide triazine polymers, cyanate ester polymers, vinyl polymers, benzoxazine polymers, benzocyclobutene polymers, acrylics, alkyds, phenol-formaldehyde polymers, novolacs, resoles, melamine-formaldehyde polymers, urea-formaldehyde polymers, hydroxymethylfurans, isocyanates, diallyl phthalate, triallyl cyanurate, triallyl isocyanurate, unsaturated polyesterimides, or the like, or a combination comprising at least one of the foregoing thermosetting polymers.

Examples of blends of thermoplastic polymers include acrylonitrile-butadiene-styrene/nylon, polycarbonate/acrylonitrile-butadiene-styrene, acrylonitrile butadiene styrene/polyvinyl chloride, polyphenylene ether/polystyrene, polyphenylene ether/nylon, polysulfone/acrylonitrile-butadiene-styrene, polycarbonate/thermoplastic urethane, polycarbonate/polyethylene terephthalate, polycarbonate/polybutylene terephthalate, thermoplastic elastomer alloys, nylon/elastomers, polyester/elastomers, polyethylene terephthalate/polybutylene terephthalate, acetal/elastomer, styrene-maleicanhydride/acrylonitrile-butadiene-styrene, polyether etherketone/polyethersulfone, polyether etherketone/polyetherimide polyethylene/nylon, polyethylene/polyacetal, or the like.

Polymers may also include biodegradable materials. Suitable examples of biodegradable polymers are as polylactic-glycolic acid (PLGA), poly-caprolactone (PCL), copolymers of polylactic-glycolic acid and poly-caprolactone (PCL-PLGA copolymer), polyhydroxy-butyrate-valerate (PHBV), polyorthoester (POE), polyethylene oxide-butylene terephthalate (PEO-PBTP), poly-D,L-lactic acid-p-dioxanone-polyethylene glycol block copolymer (PLA-DX-PEG), or the like, or combinations comprising at least one of the foregoing biodegradable polymers.

A preferred polymer for use is a thermoplastic amorphous fluoropolymer marketed under the trade name TEFLON AF. TEFLON AF is a copolymer of polytetrafluoroethylene having the molecular structure shown below:

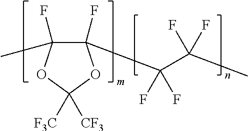

where m and n are the number of repeat units and each have independent values of 10 to 5,000, preferably 20 to 2,500, and more preferably 30 to 1,000.

Without being limited to theory, the basis of the invention is thought to lie in the ability of materials such as TEFLON AF to be thermally evaporated by cleaving into smaller chain fragments and subsequently re-polymerize on the target substrate. When co-evaporated with a small molecule electroactive (OLED) moiety, the TEFLON AF is believed to re-polymerize to some degree, forming a polymer network (such as, for example, a polymeric foam) that locks the electroactive materials (e.g., the organic semiconductor molecules that function as OLEDs) into place, preventing aggregation, crystallization, and gross morphological changes that lead to long-term degradation and/or catastrophic failure.

The interpenetrating network may be formed directly following evaporation and condensation, or in some embodiments the polymer precursor and/or the electroactive moiety may diffuse within the matrix prior to re-polymerization. The diffusion length of the polymer precursor and the electroactive moiety may be a function of the molecular size, surface energy and temperature. The diffusion may be used to control the shape and size of the formed polymer network.

In addition to this property, the organic polymer is selected to not degrade the electrical transport or light emission characteristics of the organic semiconductor (the electroactive moiety) layers that they are introduced into. In some embodiments, the organic polymer may indirectly improve electrical injection into or transport through an organic semiconductor layer. For example, organic polymers with small dipole moments may effectively reduce the dipolar energetic disorder for transport on the organic semiconductor, which can lead to reduced charge trapping and increased charge carrier mobility. In another instance, the organic polymer can indirectly improve electrical injection into the organic semiconductor by modifying the work function of the injecting electrode. In particular, fluoropolymers such as TEFLON AF may lead to improved hole injection through a similar mechanism as the well-known use of ultrathin (<5 nm) plasma-polymerized CFₓ fluorocarbon films that are used to improve hole injection into OLEDs.

A secondary benefit of adding fluoropolymers such as TEFLON AF to OLED layers is that it significantly reduces their refractive index, which helps to suppress waveguided modes and improve optical outcoupling efficiency.

In an embodiment it is desirable (a) for the polymer HOMO (highest occupied molecular orbital) to be lower in energy than the OLED molecule HOMO, the polymer LUMO (lowest unoccupied molecular orbital) to be higher than the OLED molecule LUMO, or preferably that both conditions be met. It is also desirable for the polymer chain fragments to not chemically react with the OLED molecules and that any polymer chain fragments that do no re-polymerize satisfy condition (a) above as well.

The polymer may be used in amounts of 10 to 90 vol % (volume percent), preferably 30 to 70 vol % and more preferably 40 to 60 vol %, based on the total volume of the composition. In an exemplary embodiment, the polymer is used in an amount of 25 to 50 vol %, based on the total volume of the composition.

As used herein, the term “electroactive moiety” describes a chemical functional group which is capable of transporting an electrical charge and has at least one aromatic ring, preferably two or more aromatic rings, and preferably three or more aromatic rings that are conjugated. In an embodiment, the electroactive moiety comprises a plurality of aromatic rings that are conjugated. The electrical charge can be either a positive charge or a negative charge. More specifically, as used herein, the term “electroactive moiety” describes a chemical functional group capable of transporting an electrical charge at an applied potential.

The electroactive moiety may be a host material, a hole transport layer material (HTL), a hole injection layer material (HIL), an emitter material, an electron transport layer (ETL), or the like. It is desirable for the electroactive moiety to be capable of being in vapor form at the same temperature that the monomers (or the polymer precursors) are in vapor form. While, the electroactive moiety may be capable of being in vapor form at lower or higher temperatures than the temperatures that the monomers (or the polymer precursors) are in vapor form, it is desirable for them to be capable of being in vapor form at the same temperature that the monomers (or the polymer precursors) are in vapor form.

The electroactive moieties are organic semiconductors and may include a substituted or unsubstituted carbazole compound, a substituted or unsubstituted thiophene compound, a substituted or unsubstituted sulfonyl compound, a substituted or unsubstituted phosphino compound, a substituted or unsubstituted phosphoryl compound, a substituted or unsubstituted nitrile compound, a substituted or unsubstituted fluorene compound, a substituted or unsubstituted triazine compound, a substituted or unsubstituted phenoxazine compound, a substituted or unsubstituted quinazoline compound, a substituted or unsubstituted pyridine compound, a substituted or unsubstituted benzenamine, a substituted or unsubstituted amine, or a combination thereof.

Examples of electroactive moieties are disclosed in WO2016/013867 and WO2015/099485, the entire contents of which are hereby incorporated by reference.

In an embodiment, the electroactive moiety has the structure:

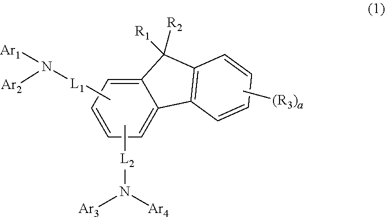

wherein L1 and L2 each independently represent a single bond, a substituted or unsubstituted (C6-C30)arylene, or a substituted or unsubstituted (3- to 30-membered)heteroarylene; Ar1 to Ar4 each independently represent a substituted or unsubstituted (C1-C30)alkyl, a substituted or unsubstituted (C3-C30)cycloalkyl, a substituted or unsubstituted (3- to 7-membered)heterocycloalkyl, a substituted or unsubstituted (C6-C30)aryl, or a substituted or unsubstituted (3- to 30-membered)heteroaryl; R1 and R2 each independently represent a substituted or unsubstituted (C1-C30)alkyl, a substituted or unsubstituted (C3-C30)cycloalkyl, a substituted or unsubstituted (3- to 7-membered)heterocycloalkyl, a substituted or unsubstituted (C6-C30)aryl, or a substituted or unsubstituted (3- to 30-membered)heteroaryl; or are linked to each other to form a mono- or polycyclic (C3-C30) alicyclic or aromatic ring; R3 represents hydrogen, deuterium, a halogen, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR4R5, —SiR6R7R8, a cyano, a nitro, or a hydroxyl; or are linked to an adjacent substituent(s) to form a mono- or polycyclic (C3-C30) alicyclic or aromatic ring; R4 and R5 each independently represent hydrogen, deuterium, a halogen, a substituted or unsubstituted (C1-C30)alkyl, a substituted or unsubstituted (C6-C30)aryl, or a substituted or unsubstituted (3- to 30-membered)heteroaryl; R6 to R8 each independently represent hydrogen, deuterium, a halogen, a substituted or unsubstituted (C1-C30)alkyl, a substituted or unsubstituted (C6-C30)aryl, a substituted or unsubstituted (3- to 30-membered)heteroaryl, a substituted or unsubstituted (3- to 7-membered)heterocycloalkyl, or a substituted or unsubstituted (C3-C30)cycloalkyl; or are linked to an adjacent substituent(s) to form a mono- or polycyclic (C3-C30) alicyclic or aromatic ring, whose carbon atom(s) may be replaced with at least one hetero atom selected from nitrogen, oxygen, and sulfur; a represents an integer of 1 to 4, where a is an integer of 2 or more, each of R3 may be the same or different; and the heteroaryl(ene) and the heterocycloalkyl each independently contain at least one hetero atom selected from B, N, O, S, P(═O), Si, and P.

Herein, “(C1-C30)alkyl” is meant to be a linear or branched alkyl having 1 to 30 carbon atoms, in which the number of carbon atoms is preferably 1 to 10, more preferably 1 to 6, and includes methyl, ethyl, n-propyl, isopropyl, n-butyl, isobutyl, tert-butyl, etc.; “(C2-C30)alkenyl” is meant to be a linear or branched alkenyl having 2 to 30 carbon atoms, in which the number of carbon atoms is preferably 2 to 20, more preferably 2 to 10, and includes vinyl, 1-propenyl, 2-propenyl, 1-butenyl, 2-butenyl, 3-butenyl, 2-methylbut-2-enyl, etc.; “(C2-C30)alkynyl” is meant to be a linear or branched alkynyl having 2 to 30 carbon atoms, in which the number of carbon atoms is preferably 2 to 20, more preferably 2 to 10, and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc.; “(3- to 7-membered)heterocycloalkyl” is a cycloalkyl having 3 to 7 ring backbone atoms, including at least one heteroatom selected from B, N, O, S, P(═O), Si, and P, preferably O, S, and N, and includes tetrahydrofuran, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20, more preferably 6 to 15, and includes phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, etc.; “(3- to 30-membered)heteroaryl(ene)” is an aryl having 3 to 30 ring backbone atoms, including at least one, preferably 1 to 4 heteroatom selected from the group consisting of B, N, O, S, P(═O), Si, and P; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzonaphthothiophenyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, C1, Br and I.

Herein, “substituted” in the expression “substituted or unsubstituted” means that a hydrogen atom in a certain functional group is replaced with another atom or group, i.e., a substituent. The substituents of the substituted (C1-C30)alkyl, the substituted (C3-C30)cycloalkyl, the substituted (3- to 7-membered)heterocycloalkyl, the substituted (C6-C30)aryl(ene), the substituted (3- to 30-membered)heteroaryl(ene), and the substituted (C6-C30)aryl(C1-C30)alkyl in L1, L2, Ar1 to Ar4, and R1 to R8 of formula 1 each independently are at least one selected from the group consisting of deuterium, a halogen, a cyano, a carboxyl, a nitro, a hydroxyl, a (C1-C30)alkyl, a halo(C1-C30)alkyl, a (C2-C30)alkenyl, a (C2-C30)alkynyl, a (C1-C30)alkoxy, a (C1-C30)alkylthio, a (C3-C30)cycloalkyl, a (C3-C30)cycloalkenyl, a (3- to 7-membered)heterocycloalkyl, a (C6-C30)aryloxy, a (C6-C30)arylthio, a (3- to 30-membered)heteroaryl unsubstituted or substituted with a (C6-C30)aryl, a (C6-C30)aryl unsubstituted or substituted with a (3- to 30-membered)heteroaryl, a tri(C1-C30)alkylsilyl, a tri(C6-C30)arylsilyl, a di(C1-C30)alkyl(C6-C30)arylsilyl, a (C1-C30)alkyldi(C6-C30)arylsilyl, an amino, a mono- or di-(C1-C30)alkylamino, a mono- or di-(C6-C30)arylamino, a (C1-C30)alkyl(C6-C30)arylamino, a (C1-C30)alkylcarbonyl, a (C1-C30)alkoxycarbonyl, a (C6-C30)arylcarbonyl, a di(C6-C30)arylboronyl, a di(C1-C30)alkylboronyl, a (C1-C30)alkyl(C6-C30)arylboronyl, a (C6-C30)aryl(C1-C30)alkyl, and a (C1-C30)alkyl(C6-C30)aryl, and preferably each independently are at least one selected from the group consisting of a (C1-C6)alkyl, a (C6-C25)aryl, and a (5- to 20-membered)heteroaryl.

In formula 1 above, L1 and L2 each independently represent a single bond, a substituted or unsubstituted (C6-C30)arylene, or a substituted or unsubstituted (3- to 30-membered)heteroarylene, preferably each independently represent a single bond, a substituted or unsubstituted (C6-C12)arylene, or a substituted or unsubstituted (5- to 20-membered)heteroarylene, and more preferably each independently represent a single bond, an unsubstituted (C6-C12)arylene, or an unsubstituted (5- to 20-membered)heteroarylene.

Ar1 to Ar4 each independently represent a substituted or unsubstituted (C1-C30)alkyl, a substituted or unsubstituted (C3-C30)cycloalkyl, a substituted or unsubstituted (3- to 7-membered)heterocycloalkyl, a substituted or unsubstituted (C6-C30)aryl, or a substituted or unsubstituted (3- to 30-membered)heteroaryl, preferably each independently represent a substituted or unsubstituted (C6-C15)aryl, and more preferably each independently represent a (C6-C15)aryl unsubstituted or substituted with a (C1-C6)alkyl, a (C6-C15)aryl, or a (5- to 20-membered)heteroaryl.

R1 and R2 each independently represent a substituted or unsubstituted (C1-C30)alkyl, a substituted or unsubstituted (C3-C30)cycloalkyl, a substituted or unsubstituted (3- to 7-membered)heterocycloalkyl, a substituted or unsubstituted (C6-C30)aryl, or a substituted or unsubstituted (3- to 30-membered)heteroaryl; or are linked to each other to form a mono- or polycyclic (C3-C30) alicyclic or aromatic ring, preferably each independently represent a substituted or unsubstituted (C1-C6)alkyl, a substituted or unsubstituted (C6-C20)aryl, or a substituted or unsubstituted (5- to 20-membered)heteroaryl; or are linked to each other to form a mono- or polycyclic (C6-C20) alicyclic or aromatic ring, and more preferably each independently represent an unsubstituted (C1-C6)alkyl; a (C6-C20)aryl unsubstituted or substituted with a (C1-C6)alkyl, a (C6-C25)aryl, or a (5- to 20-membered)heteroaryl; or a (5- to 20-membered)heteroaryl unsubstituted or substituted with a (C6-C12)aryl; or are linked to each other to form a mono- or polycyclic (C6-C20) aromatic ring.

R3 represents hydrogen, deuterium, a halogen, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR4R5, —SiR6R7R8, a cyano, a nitro, or a hydroxyl; or are linked to an adjacent substituent(s) to form a mono- or polycyclic (C3-C30) alicyclic or aromatic ring, preferably each independently represent hydrogen, a substituted or unsubstituted (C6-C12)aryl, a substituted or unsubstituted (C5-C12)cycloalkyl, —NR4R5, or —SiR6R7R8; or are linked to an adjacent substituent(s) to form a mono- or polycyclic (C6-C12) alicyclic or aromatic ring, and more preferably each independently represent hydrogen, an unsubstituted (C6-C12)aryl, an unsubstituted (C5-C12)cycloalkyl, —NR4R5, or —SiR6R7R8; or are linked to an adjacent substituent(s) to form a monocyclic (C6-C12) aromatic ring.

R4 and R5 each independently represent hydrogen, deuterium, a halogen, a substituted or unsubstituted (C1-C30)alkyl, a substituted or unsubstituted (C6-C30)aryl, or a substituted or unsubstituted (3- to 30-membered)heteroaryl, preferably each independently represent a substituted or unsubstituted (C6-C12)aryl, and more preferably each independently represent an unsubstituted (C6-C12)aryl.

R6 to R8 each independently represent hydrogen, deuterium, a halogen, a substituted or unsubstituted (C1-C30)alkyl, a substituted or unsubstituted (C6-C30)aryl, a substituted or unsubstituted (3- to 30-membered)heteroaryl, a substituted or unsubstituted (3- to 7-membered)heterocycloalkyl, or a substituted or unsubstituted (C3-C30)cycloalkyl; or are linked to an adjacent substituent(s) to form a mono- or polycyclic (C3-C30) alicyclic or aromatic ring, whose carbon atom(s) may be replaced with at least one hetero atom selected from nitrogen, oxygen, and sulfur, preferably each independently represent a substituted or unsubstituted (C1-C6)alkyl, and more preferably each independently represent an unsubstituted (C1-C6)alkyl.

A represents an integer of 1 to 4, preferably represents an integer of 1 to 2; and where a is an integer of 2 or more, each of R3 may be the same or different.

The heteroaryl(ene) and the heterocycloalkyl each independently contain at least one hetero atom selected from B, N, O, S, P(═O), Si, and P.

According to one embodiment of the present invention, in formula 1 above, L1 and L2 each independently represent a single bond, a substituted or unsubstituted (C6-C12)arylene, or a substituted or unsubstituted (5- to 20-membered)heteroarylene; Ar1 to Ar4 each independently represent a substituted or unsubstituted (C6-C15)aryl; R1 and R2 each independently represent a substituted or unsubstituted (C1-C6)alkyl, a substituted or unsubstituted (C6-C20)aryl, or a substituted or unsubstituted (5- to 20-membered)heteroaryl; or are linked to each other to form a mono- or polycyclic (C6-C20) alicyclic or aromatic ring; R3 represents hydrogen, a substituted or unsubstituted (C6-C12)aryl, a substituted or unsubstituted (C5-C12)cycloalkyl, —NR4R5, or —SiR6R7R8; or are linked to an adjacent substituent(s) to form a mono- or polycyclic (C6-C12) alicyclic or aromatic ring; R4 and R5 each independently represent a substituted or unsubstituted (C6-C12)aryl; R6 to R8 each independently represent a substituted or unsubstituted (C1-C6)alkyl; and a represents an integer of 1 to 2.

According to another embodiment of the present invention, in formula 1 above, L1 and L2 each independently represent a single bond, an unsubstituted (C6-C12)arylene, or an unsubstituted (5- to 20-membered)heteroarylene; Ar1 to Ar4 each independently represent a (C6-C15)aryl unsubstituted or substituted with a (C1-C6)alkyl, a (C6-C15)aryl, or a (5- to 20-membered)heteroaryl; R1 and R2 each independently represent an unsubstituted (C1-C6)alkyl; a (C6-C20)aryl unsubstituted or substituted with a (C1-C6)alkyl, a (C6-C25)aryl, or a (5- to 20-membered)heteroaryl; or a (5- to 20-membered)heteroaryl unsubstituted or substituted with a (C6-C12)aryl; or are linked to each other to form a mono- or polycyclic (C6-C20) aromatic ring; R3 represents hydrogen, an unsubstituted (C6-C12)aryl, an unsubstituted (C5-C12)cycloalkyl, —NR4R5, or —SiR6R7R8; or are linked to an adjacent substituent(s) to form a monocyclic (C6-C12) aromatic ring; R4 and R5 each independently represent an unsubstituted (C6-C12)aryl; R6 to R8 each independently represent an unsubstituted (C1-C6)alkyl; and a represents an integer of 1 to 2.

Examples of the formula (1) that may be used as electroactive moieties include

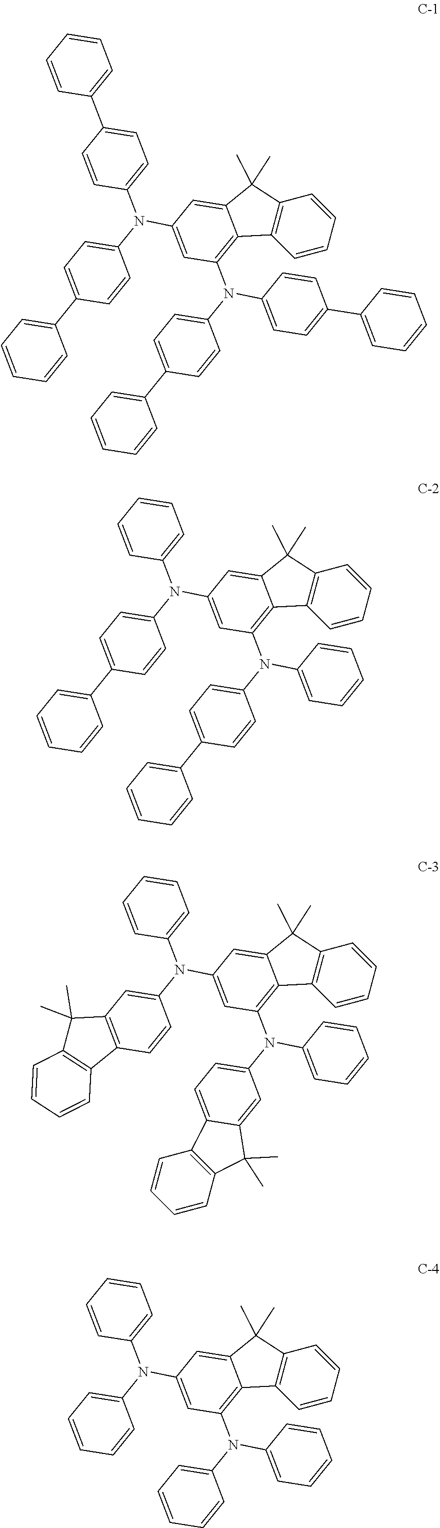

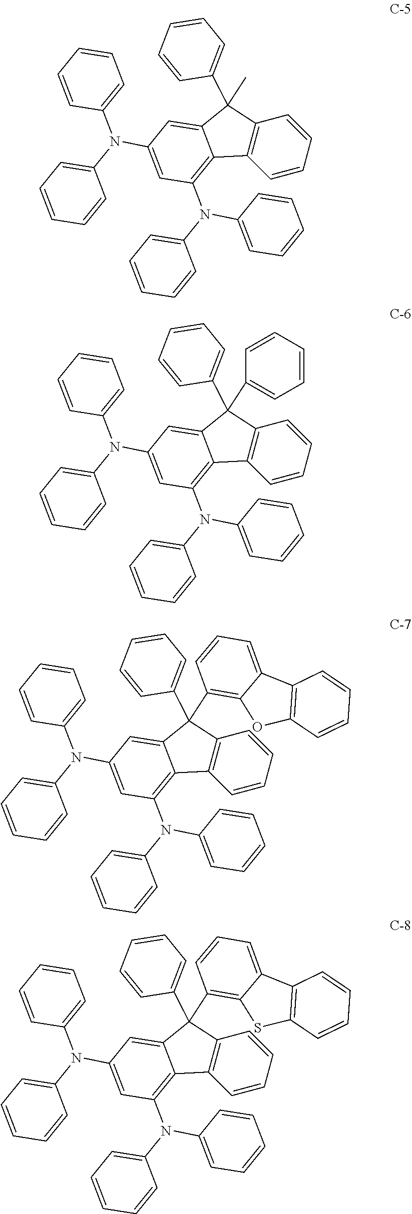

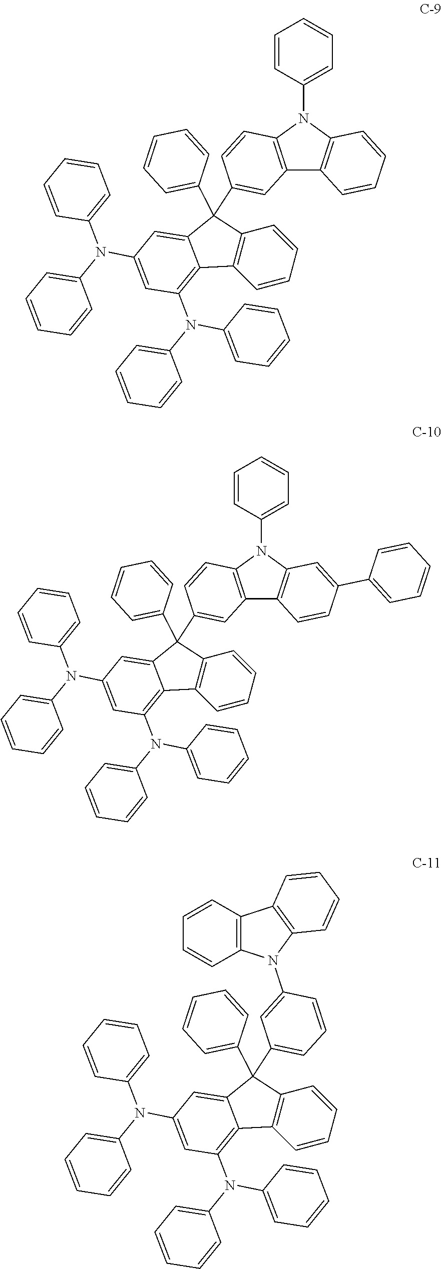 [SMILES: c1ccc(N(c2ccccc2)c2cc(N(c3ccccc3)c3ccccc3)c3c(c2)C(c2ccccc2)(c2ccc4c(c2)c2ccccc2n4-c2ccccc2)c2ccccc2-3)cc1 ; c1ccc(-c2ccc3c4cc(C5(c6ccccc6)c6ccccc6-c6c(N(c7ccccc7)c7ccccc7)cc(N(c7ccccc7)c7ccccc7)cc65)ccc4n(-c4ccccc4)c3c2)cc1 ; c1ccc(N(c2ccccc2)c2cc(N(c3ccccc3)c3ccccc3)c3c(c2)C(c2ccccc2)(c2cccc(-n4c5ccccc5c5ccccc54)c2)c2ccccc2-3)cc1]

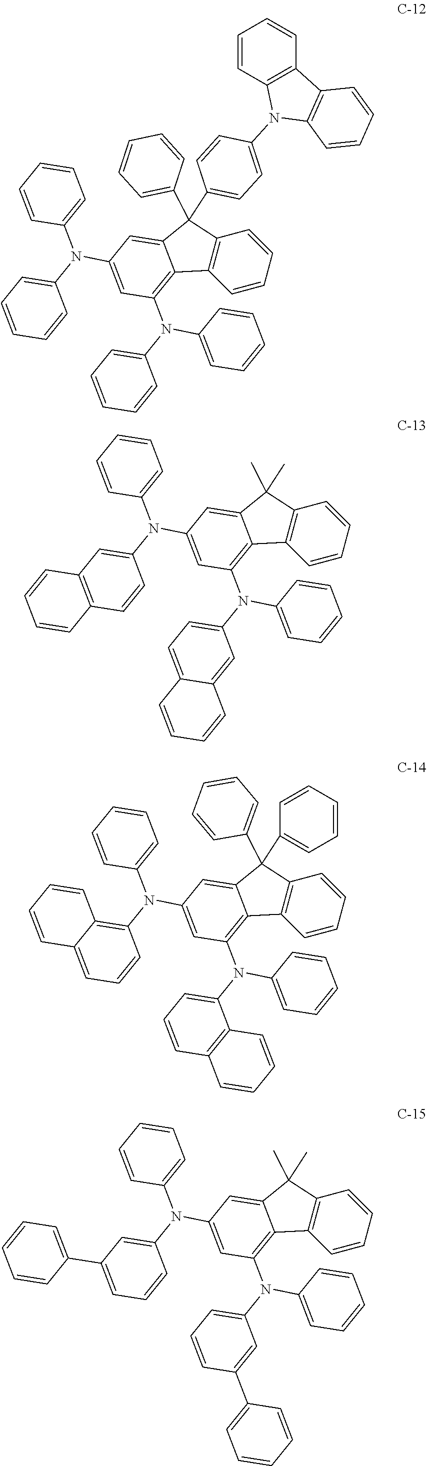

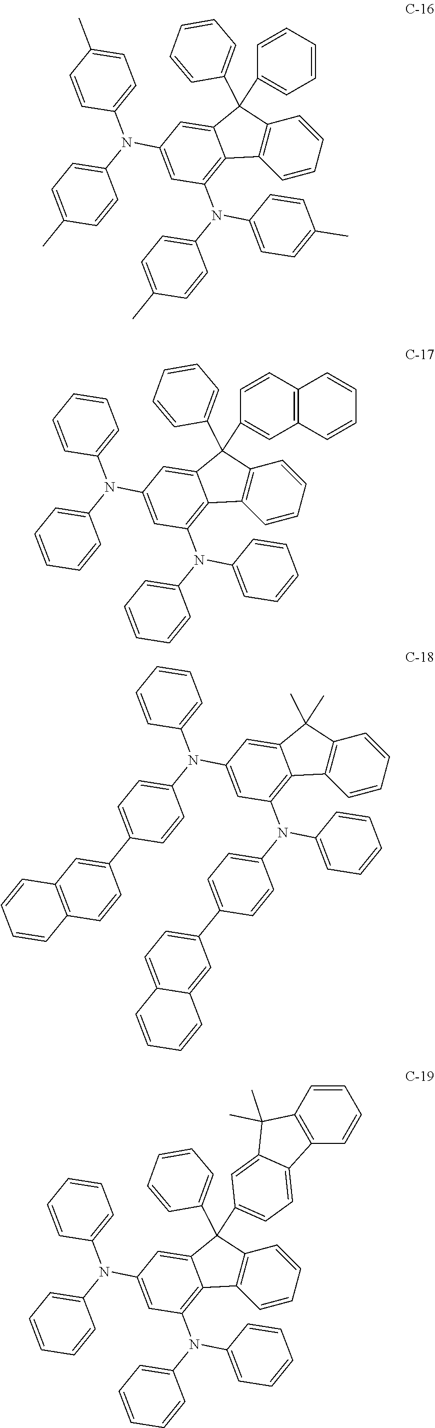

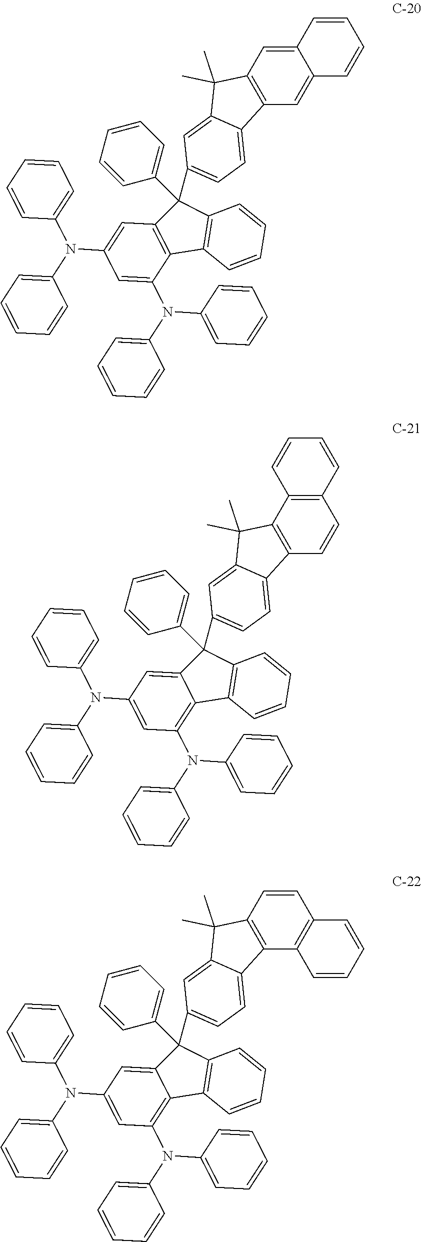 [SMILES: CC1(C)c2cc(C3(c4ccccc4)c4ccccc4-c4c(N(c5ccccc5)c5ccccc5)cc(N(c5ccccc5)c5ccccc5)cc43)ccc2-c2cc3ccccc3cc21 ; CC1(C)c2cc(C3(c4ccccc4)c4ccccc4-c4c(N(c5ccccc5)c5ccccc5)cc(N(c5ccccc5)c5ccccc5)cc43)ccc2-c2ccc3ccccc3c21 ; CC1(C)c2cc(C3(c4ccccc4)c4ccccc4-c4c(N(c5ccccc5)c5ccccc5)cc(N(c5ccccc5)c5ccccc5)cc43)ccc2-c2c1ccc1ccccc21]

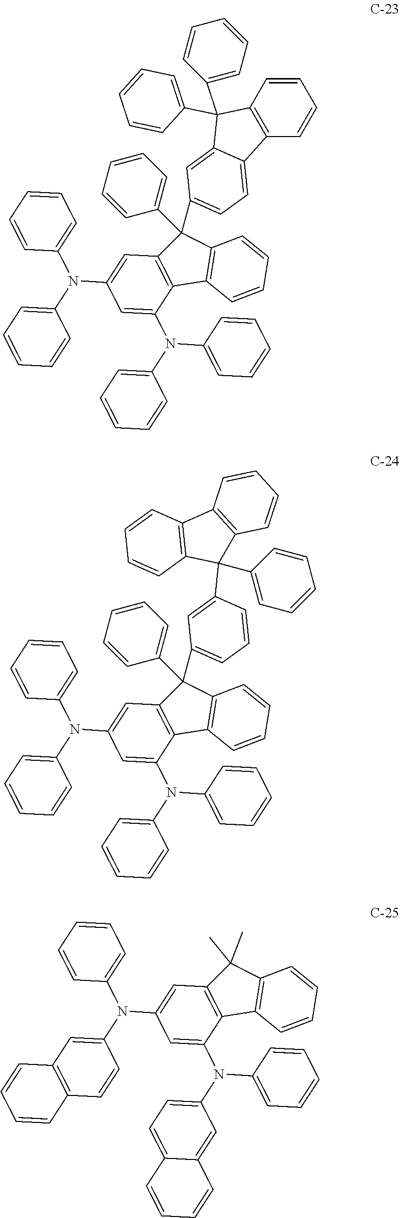 [SMILES: c1ccc(N(c2ccccc2)c2cc(N(c3ccccc3)c3ccccc3)c3c(c2)C(c2ccccc2)(c2ccc4c(c2)C(c2ccccc2)(c2ccccc2)c2ccccc2-4)c2ccccc2-3)cc1 ; c1ccc(N(c2ccccc2)c2cc(N(c3ccccc3)c3ccccc3)c3c(c2)C(c2ccccc2)(c2cccc(C4(c5ccccc5)c5ccccc5-c5ccccc54)c2)c2ccccc2-3)cc1 ; CC1(C)c2ccccc2-c2c(N(c3ccccc3)c3ccc4ccccc4c3)cc(N(c3ccccc3)c3ccc4ccccc4c3)cc21]

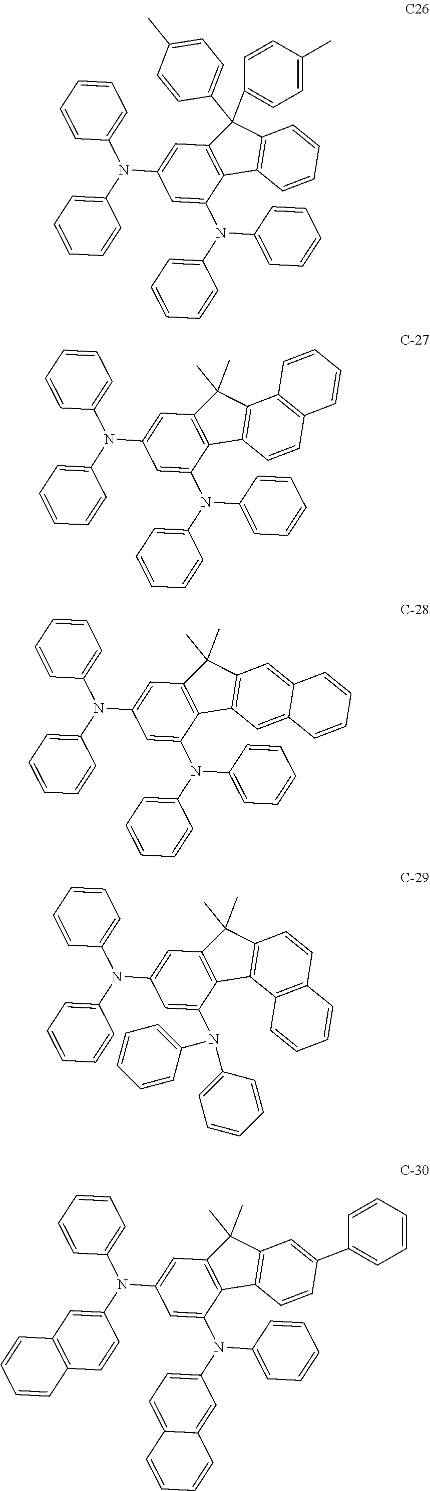

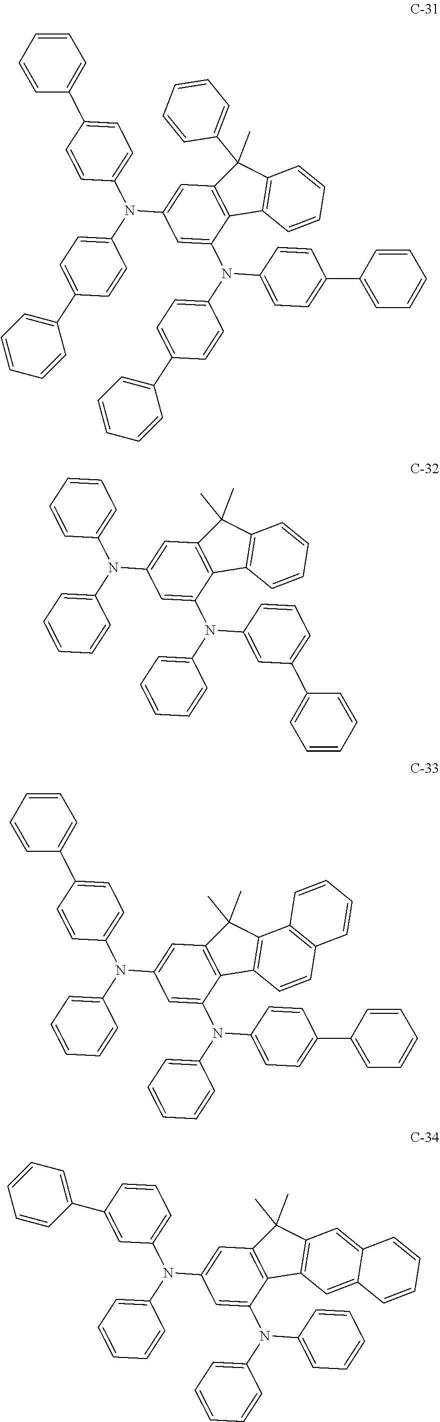 [SMILES: CC1(c2ccccc2)c2ccccc2-c2c(N(c3ccc(-c4ccccc4)cc3)c3ccc(-c4ccccc4)cc3)cc(N(c3ccc(-c4ccccc4)cc3)c3ccc(-c4ccccc4)cc3)cc21 ; CC1(C)c2ccccc2-c2c(N(c3ccccc3)c3cccc(-c4ccccc4)c3)cc(N(c3ccccc3)c3ccccc3)cc21 ; CC1(C)c2cc(N(c3ccccc3)c3ccc(-c4ccccc4)cc3)cc(N(c3ccccc3)c3ccc(-c4ccccc4)cc3)c2-c2ccc3ccccc3c21 ; CC1(C)c2cc3ccccc3cc2-c2c(N(c3ccccc3)c3ccccc3)cc(N(c3ccccc3)c3cccc(-c4ccccc4)c3)cc21]

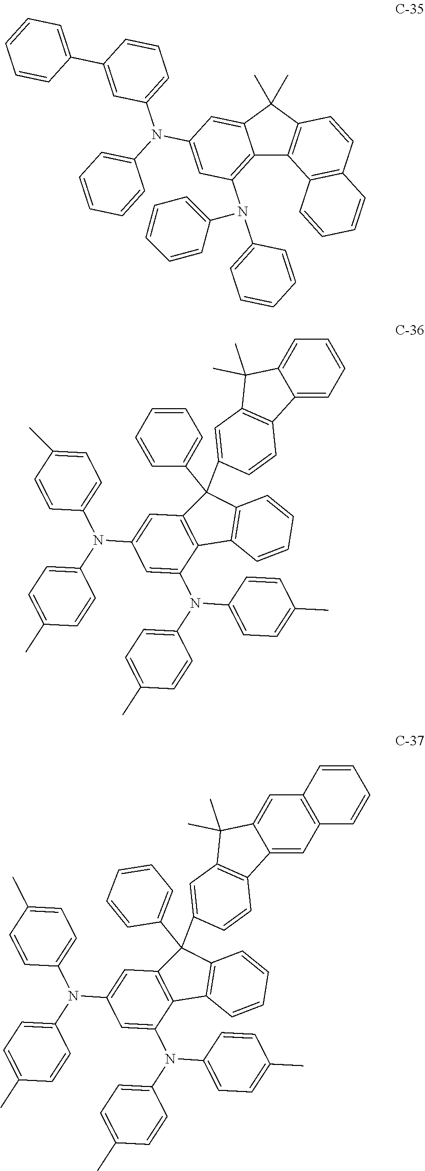

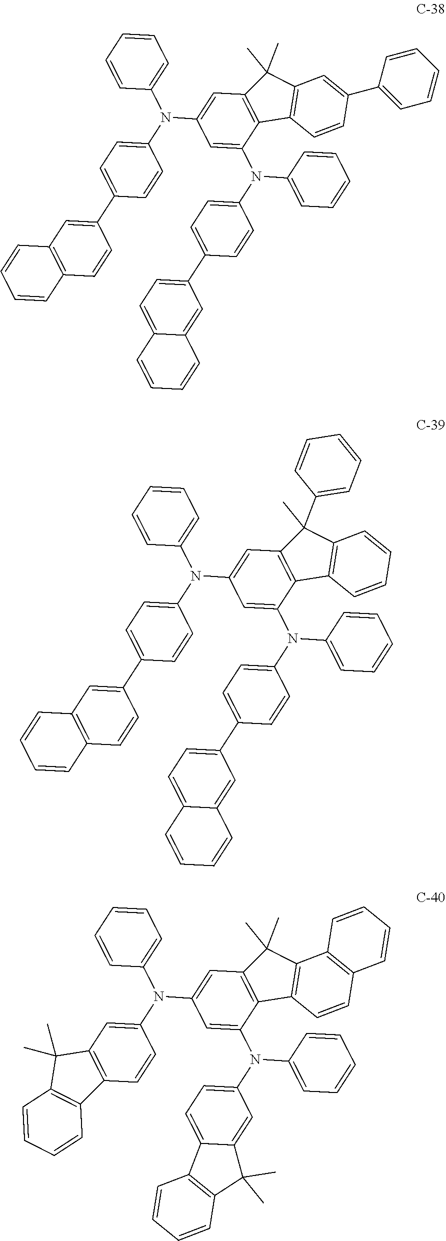 [SMILES: CC1(C)c2cc(-c3ccccc3)ccc2-c2c(N(c3ccccc3)c3ccc(-c4ccc5ccccc5c4)cc3)cc(N(c3ccccc3)c3ccc(-c4ccc5ccccc5c4)cc3)cc21 ; CC1(c2ccccc2)c2ccccc2-c2c(N(c3ccccc3)c3ccc(-c4ccc5ccccc5c4)cc3)cc(N(c3ccccc3)c3ccc(-c4ccc5ccccc5c4)cc3)cc21 ; CC1(C)c2ccccc2-c2ccc(N(c3ccccc3)c3cc(N(c4ccccc4)c4ccc5c(c4)C(C)(C)c4ccccc4-5)c4c(c3)C(C)(C)c3c-4ccc4ccccc34)cc21]

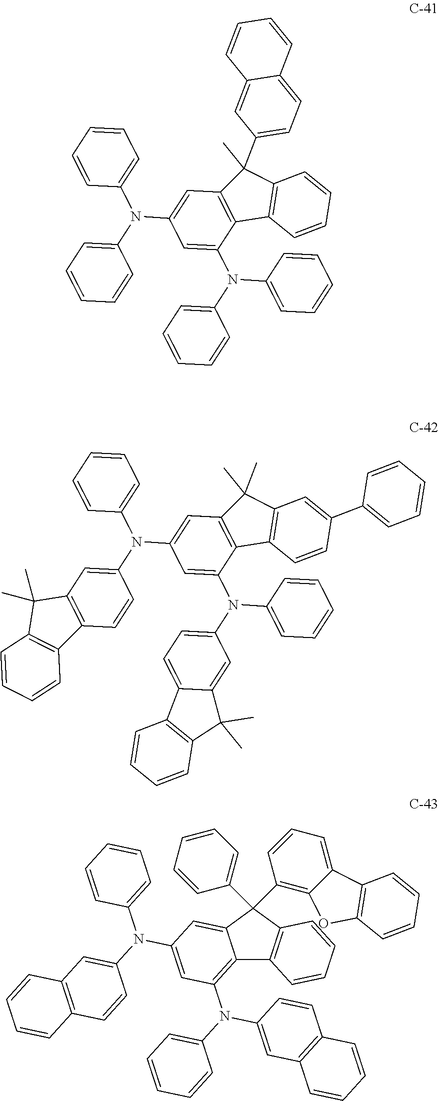 [SMILES: CC1(c2ccc3ccccc3c2)c2ccccc2-c2c(N(c3ccccc3)c3ccccc3)cc(N(c3ccccc3)c3ccccc3)cc21 ; CC1(C)c2ccccc2-c2ccc(N(c3ccccc3)c3cc(N(c4ccccc4)c4ccc5c(c4)C(C)(C)c4ccccc4-5)c4c(c3)C(C)(C)c3cc(-c5ccccc5)ccc3-4)cc21 ; c1ccc(N(c2cc(N(c3ccccc3)c3ccc4ccccc4c3)c3c(c2)C(c2ccccc2)(c2cccc4c2oc2ccccc24)c2ccccc2-3)c2ccc3ccccc3c2)cc1]

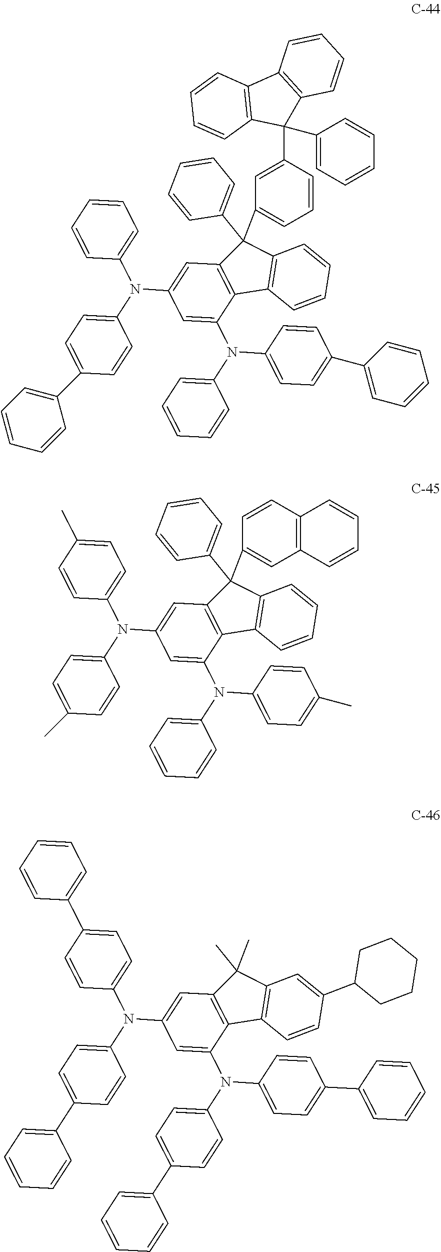 [SMILES: c1ccc(-c2ccc(N(c3ccccc3)c3cc(N(c4ccccc4)c4ccc(-c5ccccc5)cc4)c4c(c3)C(c3ccccc3)(c3cccc(C5(c6ccccc6)c6ccccc6-c6ccccc65)c3)c3ccccc3-4)cc2)cc1 ; Cc1ccc(N(c2ccc(C)cc2)c2cc(N(c3ccccc3)c3ccc(C)cc3)c3c(c2)C(c2ccccc2)(c2ccc4ccccc4c2)c2ccccc2-3)cc1 ; CC1(C)c2cc(C3CCCCC3)ccc2-c2c(N(c3ccc(-c4ccccc4)cc3)c3ccc(-c4ccccc4)cc3)cc(N(c3ccc(-c4ccccc4)cc3)c3ccc(-c4ccccc4)cc3)cc21]

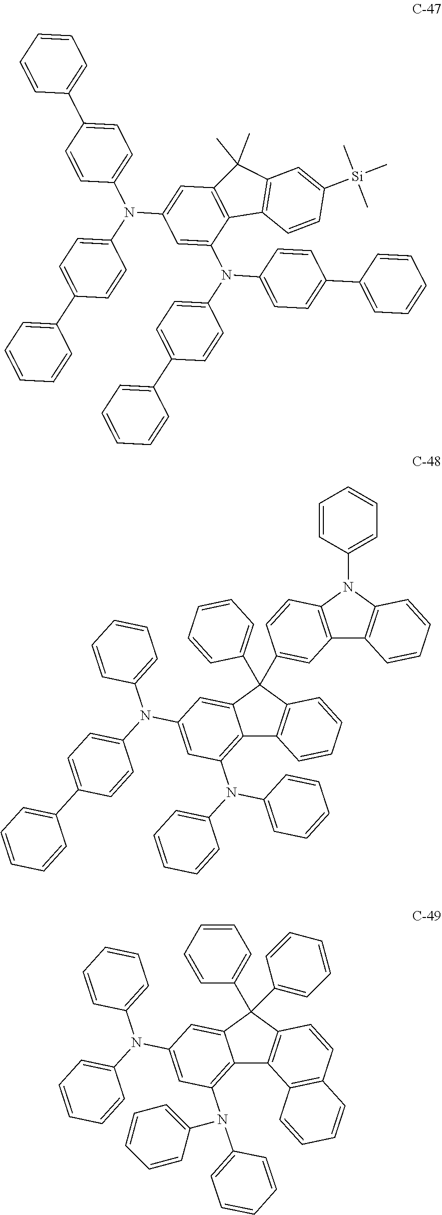 [SMILES: CC1(C)c2cc([Si](C)(C)C)ccc2-c2c(N(c3ccc(-c4ccccc4)cc3)c3ccc(-c4ccccc4)cc3)cc(N(c3ccc(-c4ccccc4)cc3)c3ccc(-c4ccccc4)cc3)cc21 ; c1ccc(-c2ccc(N(c3ccccc3)c3cc(N(c4ccccc4)c4ccccc4)c4c(c3)C(c3ccccc3)(c3ccc5c(c3)c3ccccc3n5-c3ccccc3)c3ccccc3-4)cc2)cc1 ; c1ccc(N(c2ccccc2)c2cc(N(c3ccccc3)c3ccccc3)c3c(c2)C(c2ccccc2)(c2ccccc2)c2ccc4ccccc4c2-3)cc1]

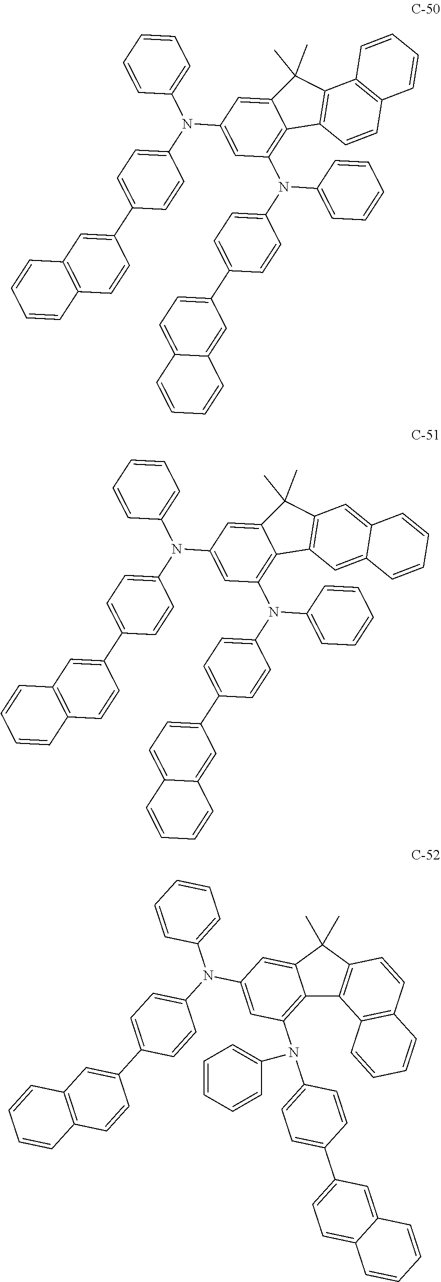

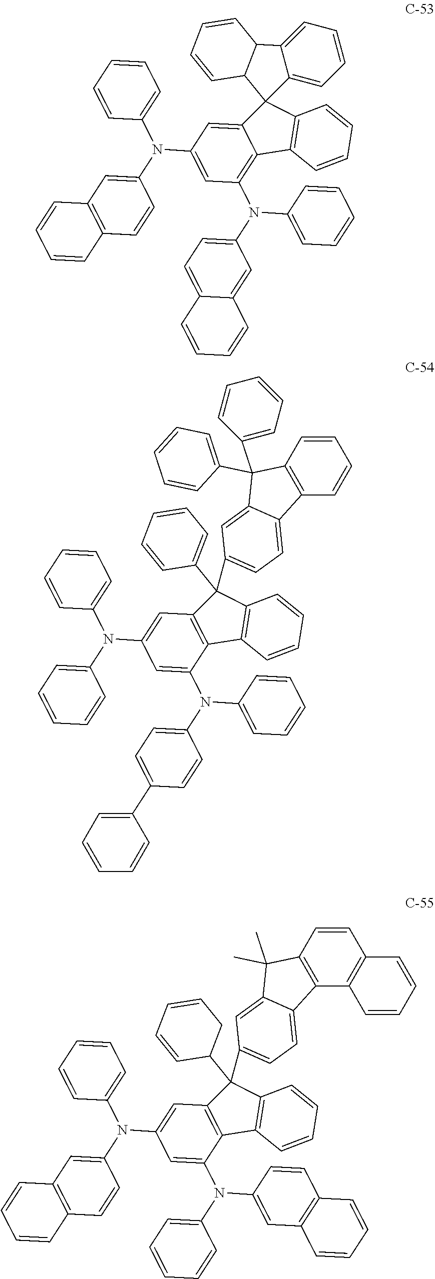

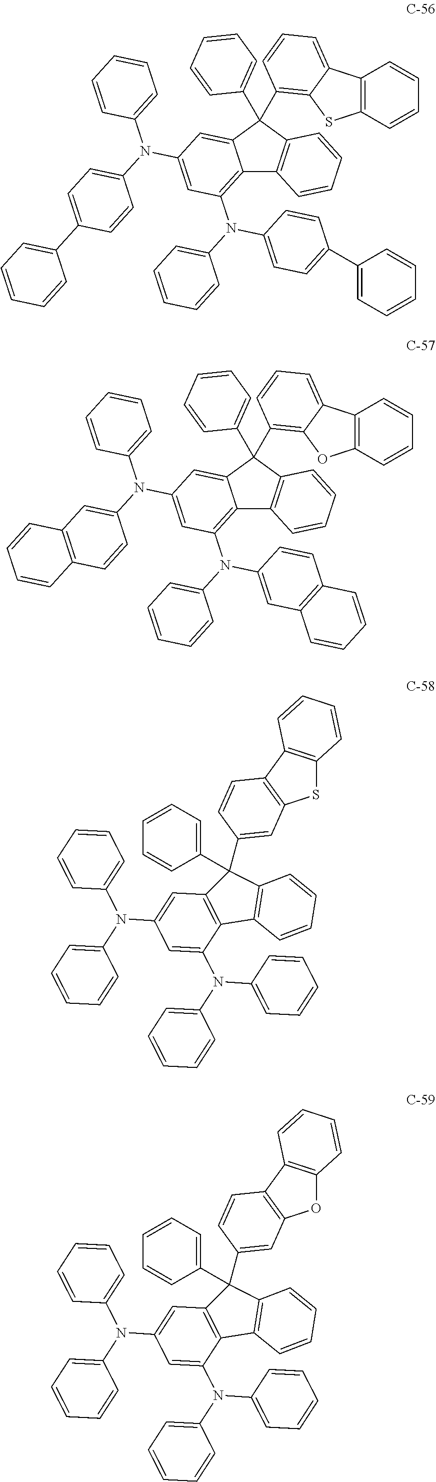 [SMILES: c1ccc(-c2ccc(N(c3ccccc3)c3cc(N(c4ccccc4)c4ccc(-c5ccccc5)cc4)c4c(c3)C(c3ccccc3)(c3cccc5c3sc3ccccc35)c3ccccc3-4)cc2)cc1 ; c1ccc(N(c2cc(N(c3ccccc3)c3ccc4ccccc4c3)c3c(c2)C(c2ccccc2)(c2cccc4c2oc2ccccc24)c2ccccc2-3)c2ccc3ccccc3c2)cc1 ; c1ccc(N(c2ccccc2)c2cc(N(c3ccccc3)c3ccccc3)c3c(c2)C(c2ccccc2)(c2ccc4c(c2)sc2ccccc24)c2ccccc2-3)cc1 ; c1ccc(N(c2ccccc2)c2cc(N(c3ccccc3)c3ccccc3)c3c(c2)C(c2ccccc2)(c2ccc4c(c2)oc2ccccc24)c2ccccc2-3)cc1]

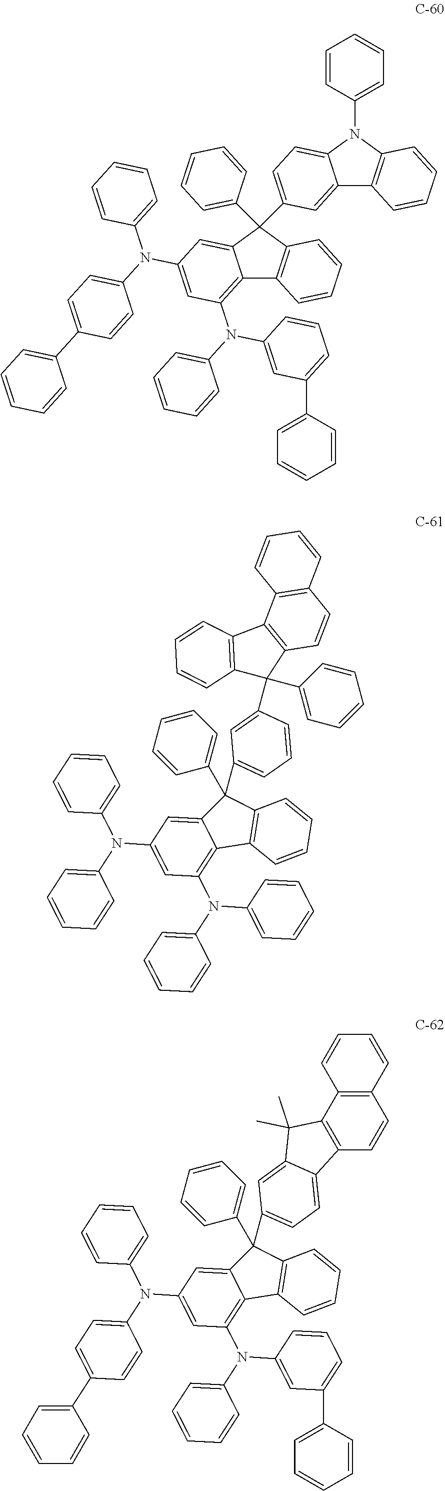 [SMILES: c1ccc(-c2ccc(N(c3ccccc3)c3cc(N(c4ccccc4)c4cccc(-c5ccccc5)c4)c4c(c3)C(c3ccccc3)(c3ccc5c(c3)c3ccccc3n5-c3ccccc3)c3ccccc3-4)cc2)cc1 ; c1ccc(N(c2ccccc2)c2cc(N(c3ccccc3)c3ccccc3)c3c(c2)C(c2ccccc2)(c2cccc(C4(c5ccccc5)c5ccccc5-c5c4ccc4ccccc54)c2)c2ccccc2-3)cc1 ; CC1(C)c2cc(C3(c4ccccc4)c4ccccc4-c4c(N(c5ccccc5)c5cccc(-c6ccccc6)c5)cc(N(c5ccccc5)c5ccc(-c6ccccc6)cc5)cc43)ccc2-c2ccc3ccccc3c21]

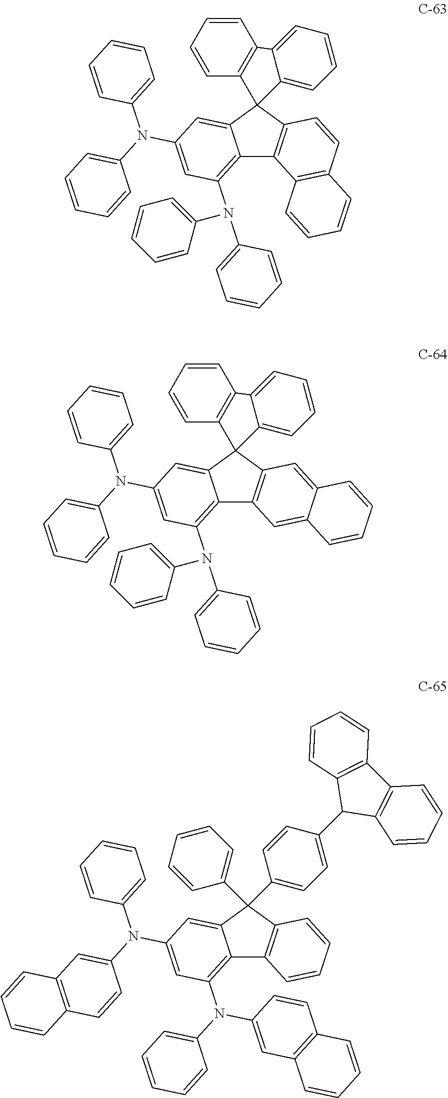 [SMILES: c1ccc(N(c2ccccc2)c2cc(N(c3ccccc3)c3ccccc3)c3c(c2)C2(c4ccccc4-c4ccccc42)c2ccc4ccccc4c2-3)cc1 ; c1ccc(N(c2ccccc2)c2cc(N(c3ccccc3)c3ccccc3)c3c(c2)C2(c4ccccc4-c4ccccc42)c2cc4ccccc4cc2-3)cc1 ; c1ccc(N(c2cc(N(c3ccccc3)c3ccc4ccccc4c3)c3c(c2)C(c2ccccc2)(c2ccc(C4c5ccccc5-c5ccccc54)cc2)c2ccccc2-3)c2ccc3ccccc3c2)cc1]

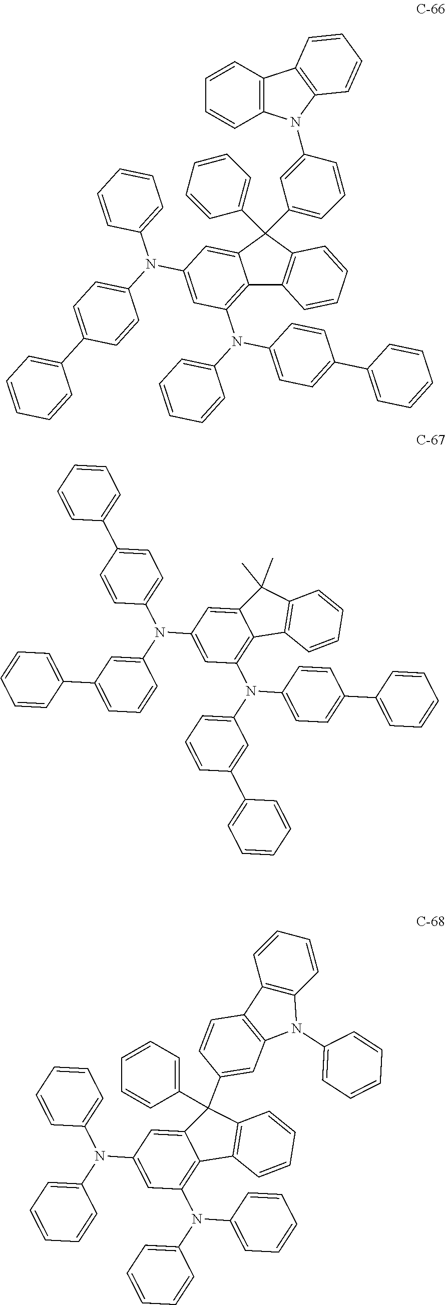 [SMILES: c1ccc(-c2ccc(N(c3ccccc3)c3cc(N(c4ccccc4)c4ccc(-c5ccccc5)cc4)c4c(c3)C(c3ccccc3)(c3cccc(-n5c6ccccc6c6ccccc65)c3)c3ccccc3-4)cc2)cc1 ; CC1(C)c2ccccc2-c2c(N(c3ccc(-c4ccccc4)cc3)c3cccc(-c4ccccc4)c3)cc(N(c3ccc(-c4ccccc4)cc3)c3cccc(-c4ccccc4)c3)cc21 ; c1ccc(N(c2ccccc2)c2cc(N(c3ccccc3)c3ccccc3)c3c(c2)C(c2ccccc2)(c2ccc4c5ccccc5n(-c5ccccc5)c4c2)c2ccccc2-3)cc1]

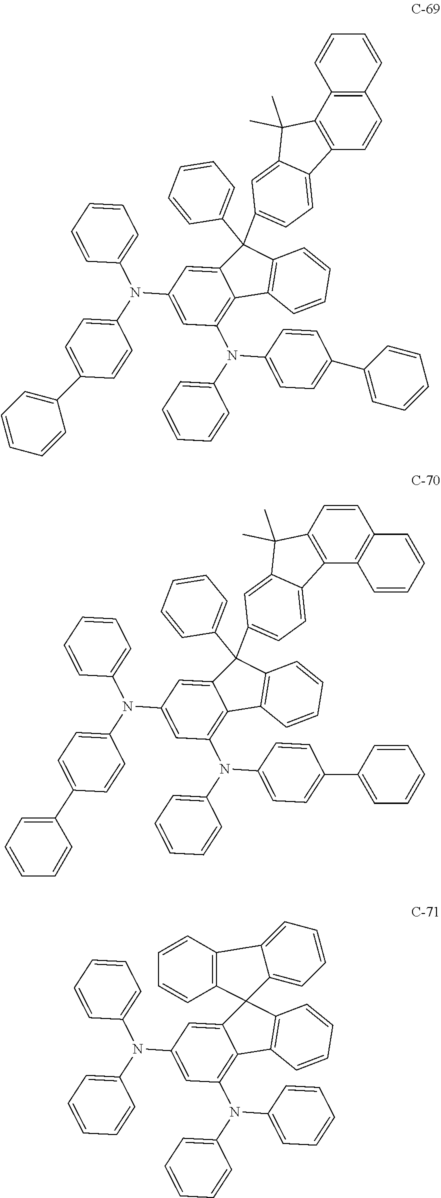 [SMILES: CC1(C)c2cc(C3(c4ccccc4)c4ccccc4-c4c(N(c5ccccc5)c5ccc(-c6ccccc6)cc5)cc(N(c5ccccc5)c5ccc(-c6ccccc6)cc5)cc43)ccc2-c2ccc3ccccc3c21 ; CC1(C)c2cc(C3(c4ccccc4)c4ccccc4-c4c(N(c5ccccc5)c5ccc(-c6ccccc6)cc5)cc(N(c5ccccc5)c5ccc(-c6ccccc6)cc5)cc43)ccc2-c2c1ccc1ccccc21 ; c1ccc(N(c2ccccc2)c2cc(N(c3ccccc3)c3ccccc3)c3c(c2)C2(c4ccccc4-c4ccccc42)c2ccccc2-3)cc1]

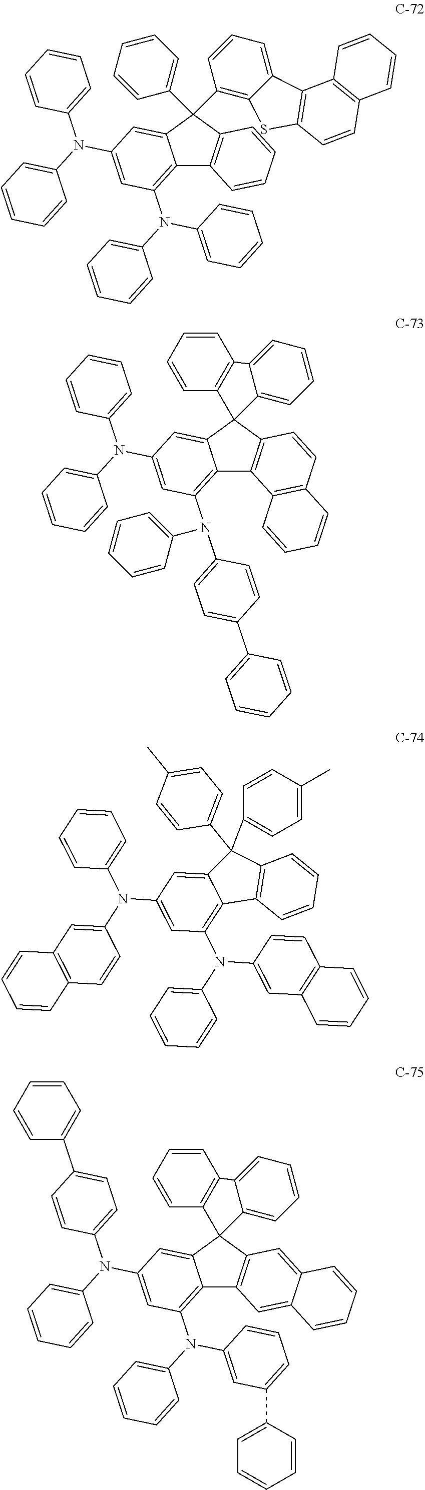

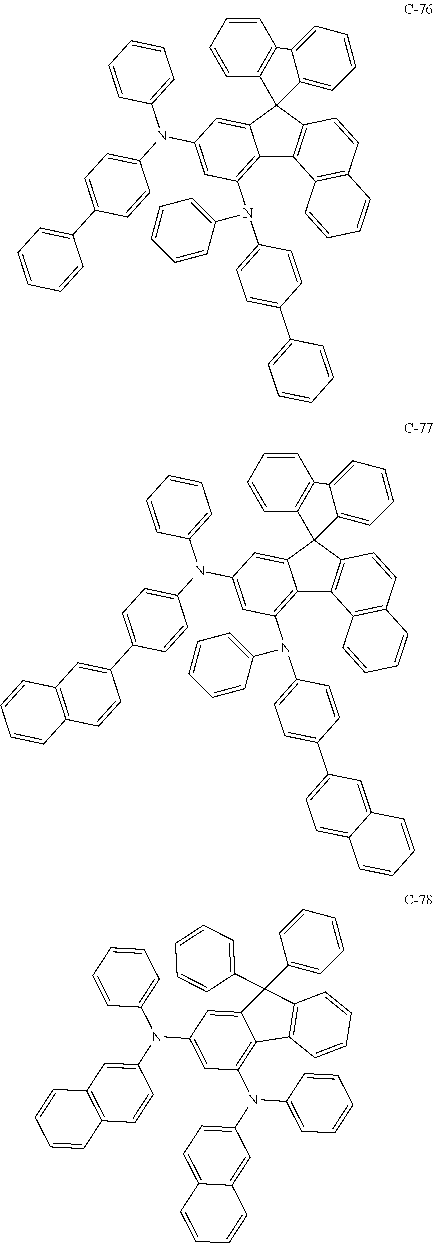 [SMILES: c1ccc(-c2ccc(N(c3ccccc3)c3cc(N(c4ccccc4)c4ccc(-c5ccccc5)cc4)c4c(c3)C3(c5ccccc5-c5ccccc53)c3ccc5ccccc5c3-4)cc2)cc1 ; c1ccc(N(c2ccc(-c3ccc4ccccc4c3)cc2)c2cc(N(c3ccccc3)c3ccc(-c4ccc5ccccc5c4)cc3)c3c(c2)C2(c4ccccc4-c4ccccc42)c2ccc4ccccc4c2-3)cc1 ; c1ccc(N(c2cc(N(c3ccccc3)c3ccc4ccccc4c3)c3c(c2)C(c2ccccc2)(c2ccccc2)c2ccccc2-3)c2ccc3ccccc3c2)cc1]

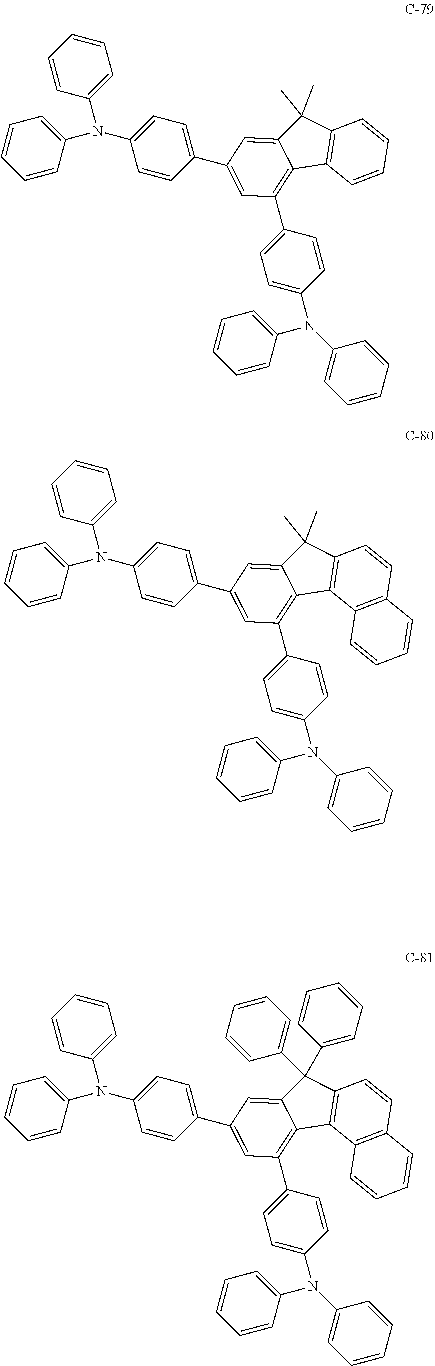 [SMILES: CC1(C)c2ccccc2-c2c(-c3ccc(N(c4ccccc4)c4ccccc4)cc3)cc(-c3ccc(N(c4ccccc4)c4ccccc4)cc3)cc21 ; CC1(C)c2cc(-c3ccc(N(c4ccccc4)c4ccccc4)cc3)cc(-c3ccc(N(c4ccccc4)c4ccccc4)cc3)c2-c2c1ccc1ccccc21 ; c1ccc(N(c2ccccc2)c2ccc(-c3cc(-c4ccc(N(c5ccccc5)c5ccccc5)cc4)c4c(c3)C(c3ccccc3)(c3ccccc3)c3ccc5ccccc5c3-4)cc2)cc1]

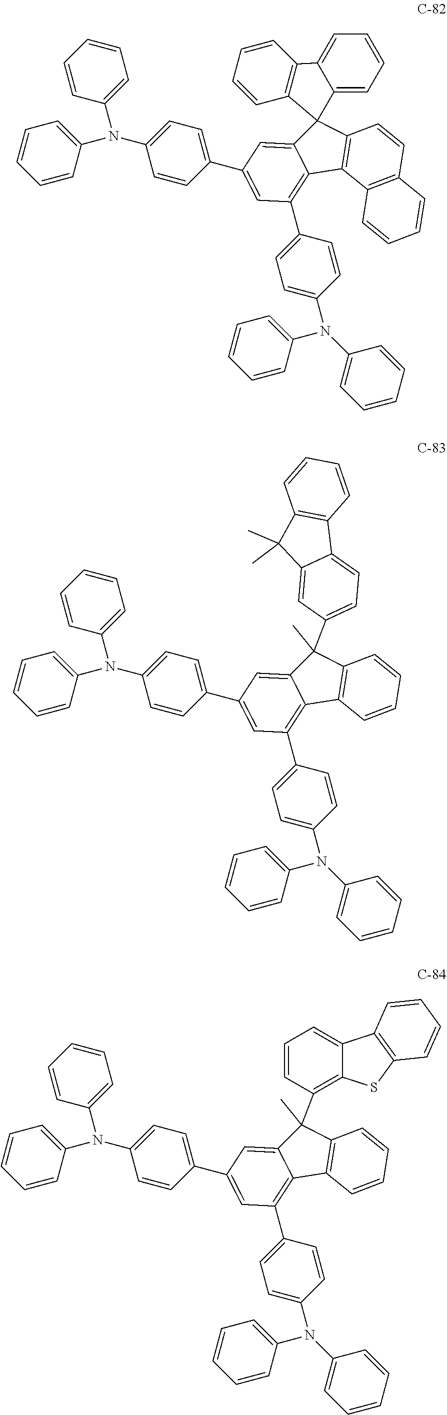 [SMILES: c1ccc(N(c2ccccc2)c2ccc(-c3cc(-c4ccc(N(c5ccccc5)c5ccccc5)cc4)c4c(c3)C3(c5ccccc5-c5ccccc53)c3ccc5ccccc5c3-4)cc2)cc1 ; CC1(C)c2ccccc2-c2ccc(C3(C)c4ccccc4-c4c(-c5ccc(N(c6ccccc6)c6ccccc6)cc5)cc(-c5ccc(N(c6ccccc6)c6ccccc6)cc5)cc43)cc21 ; CC1(c2cccc3c2sc2ccccc23)c2ccccc2-c2c(-c3ccc(N(c4ccccc4)c4ccccc4)cc3)cc(-c3ccc(N(c4ccccc4)c4ccccc4)cc3)cc21]

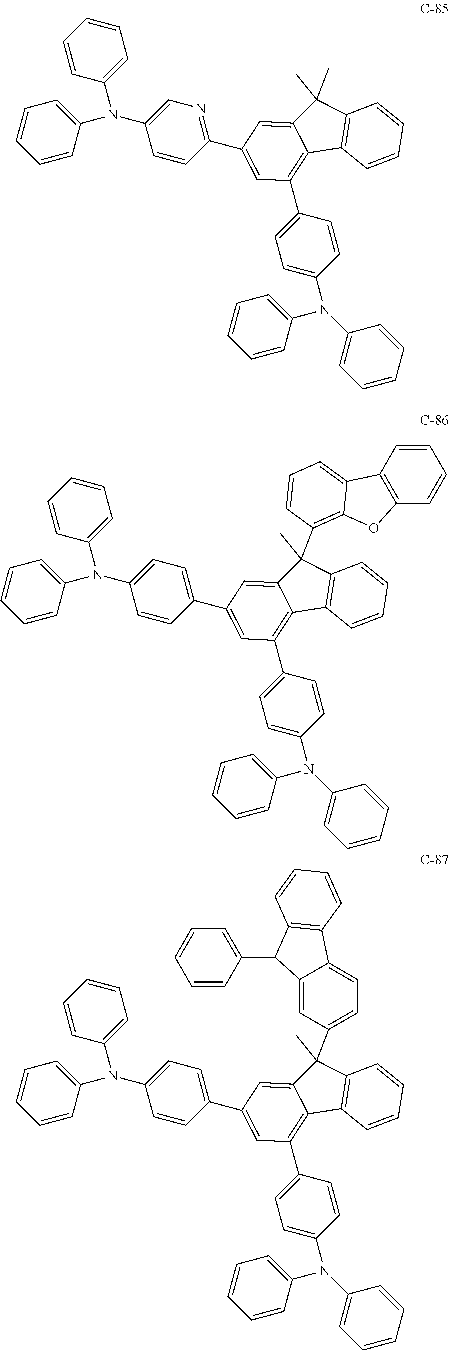

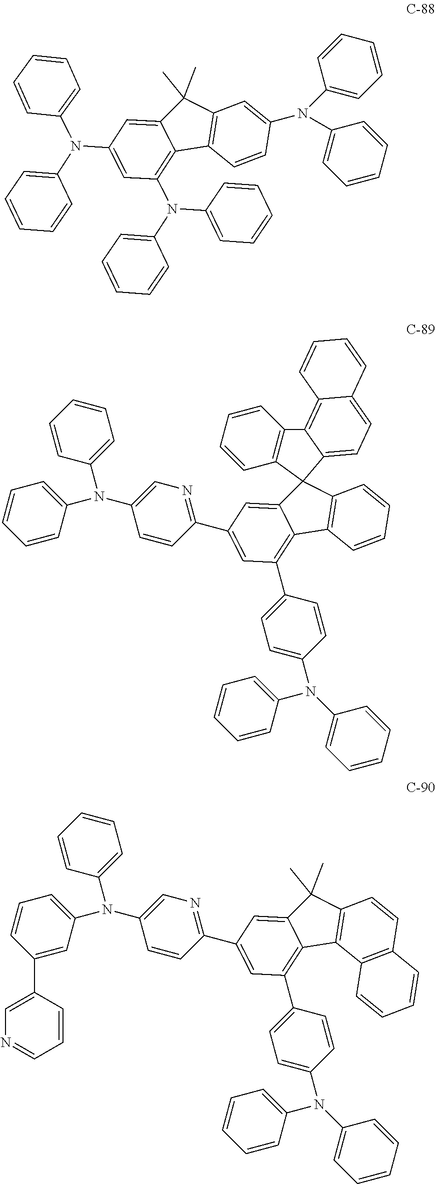 [SMILES: CC1(C)c2cc(N(c3ccccc3)c3ccccc3)ccc2-c2c(N(c3ccccc3)c3ccccc3)cc(N(c3ccccc3)c3ccccc3)cc21 ; c1ccc(N(c2ccccc2)c2ccc(-c3cc(-c4ccc(N(c5ccccc5)c5ccccc5)cn4)cc4c3-c3ccccc3C43c4ccccc4-c4c3ccc3ccccc43)cc2)cc1 ; CC1(C)c2cc(-c3ccc(N(c4ccccc4)c4cccc(-c5cccnc5)c4)cn3)cc(-c3ccc(N(c4ccccc4)c4ccccc4)cc3)c2-c2c1ccc1ccccc21]

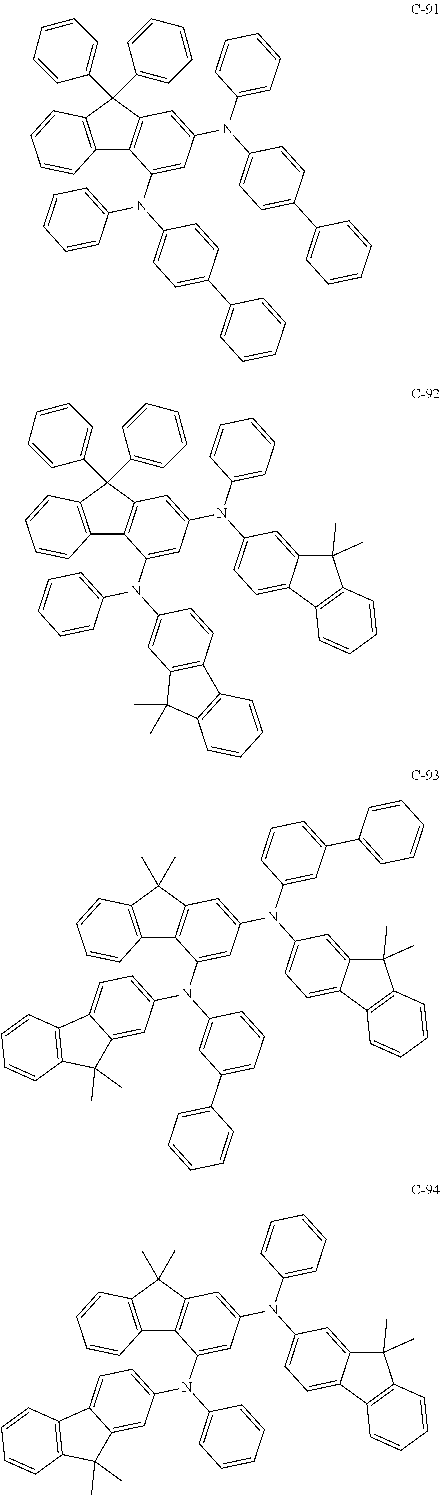 [SMILES: c1ccc(-c2ccc(N(c3ccccc3)c3cc(N(c4ccccc4)c4ccc(-c5ccccc5)cc4)c4c(c3)C(c3ccccc3)(c3ccccc3)c3ccccc3-4)cc2)cc1 ; CC1(C)c2ccccc2-c2ccc(N(c3ccccc3)c3cc(N(c4ccccc4)c4ccc5c(c4)C(C)(C)c4ccccc4-5)c4c(c3)C(c3ccccc3)(c3ccccc3)c3ccccc3-4)cc21 ; CC1(C)c2ccccc2-c2ccc(N(c3cccc(-c4ccccc4)c3)c3cc(N(c4cccc(-c5ccccc5)c4)c4ccc5c(c4)C(C)(C)c4ccccc4-5)c4c(c3)C(C)(C)c3ccccc3-4)cc21 ; CC1(C)c2ccccc2-c2ccc(N(c3ccccc3)c3cc(N(c4ccccc4)c4ccc5c(c4)C(C)(C)c4ccccc4-5)c4c(c3)C(C)(C)c3ccccc3-4)cc21]

Other examples of electroactive moieties include:

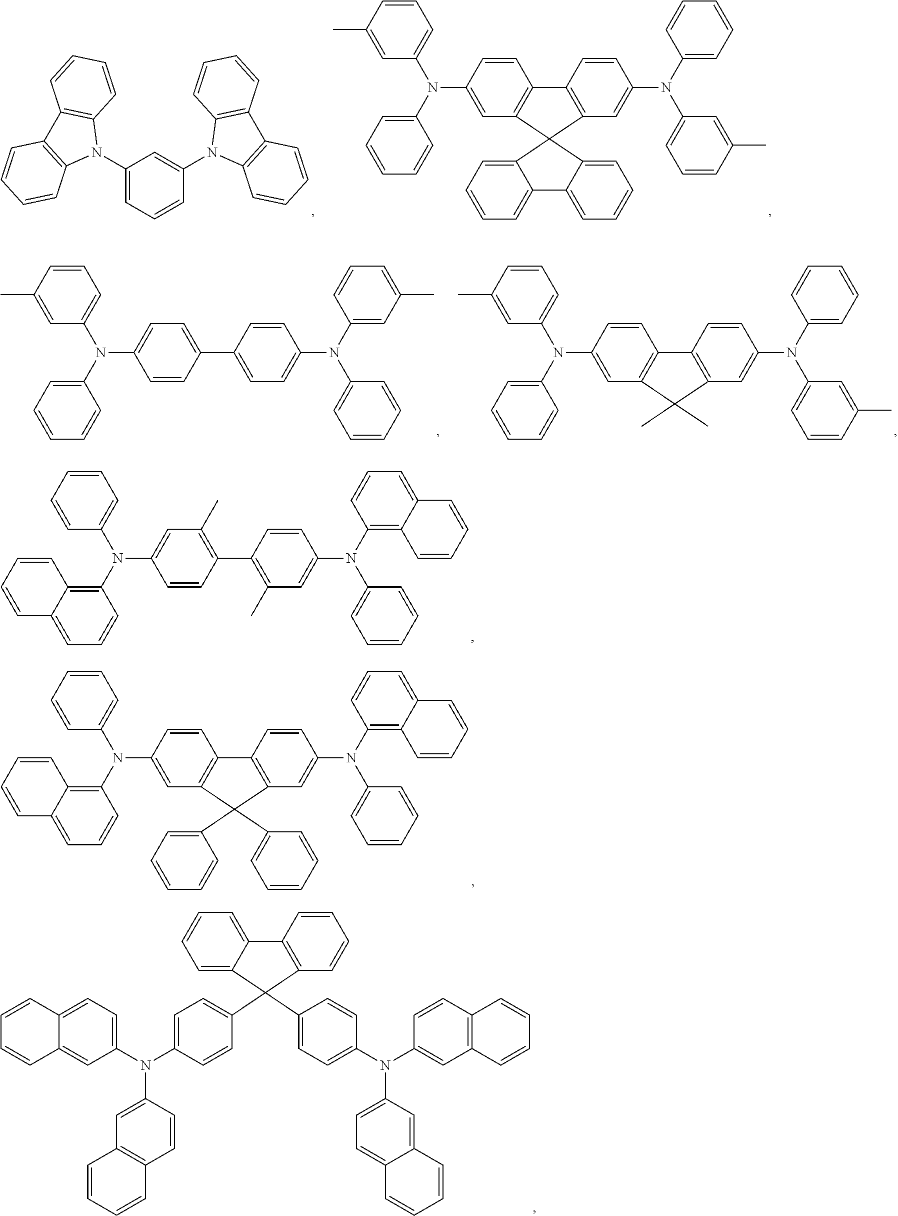

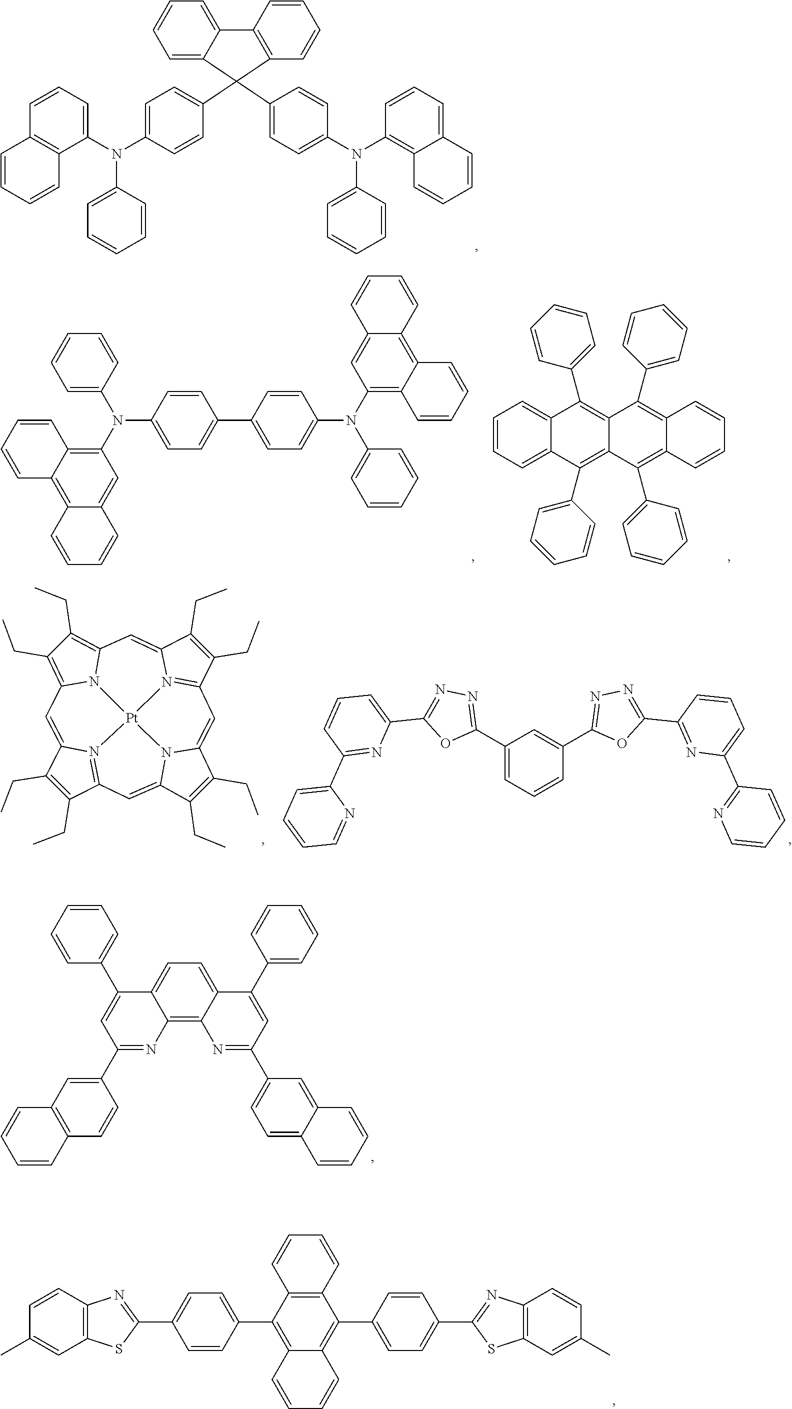

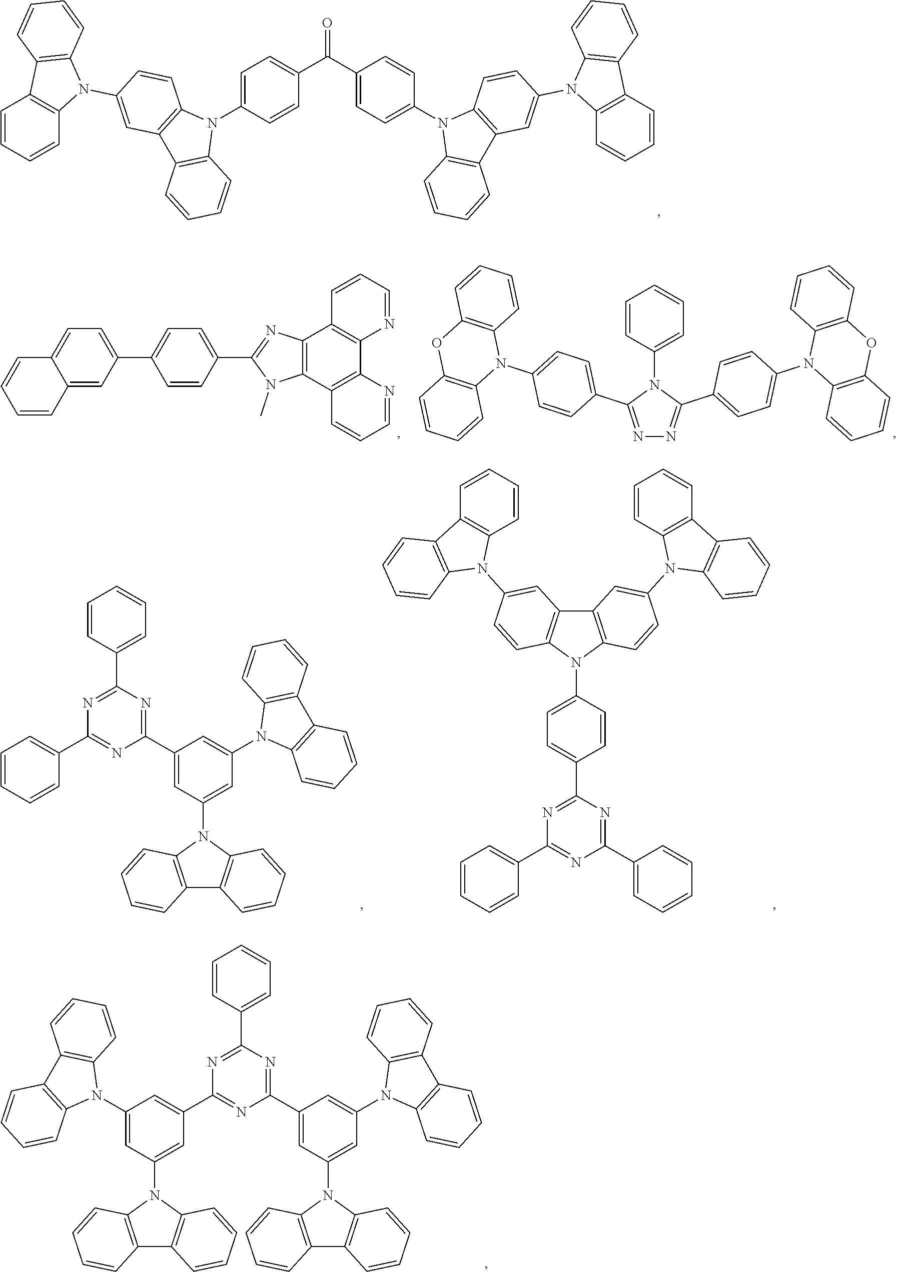

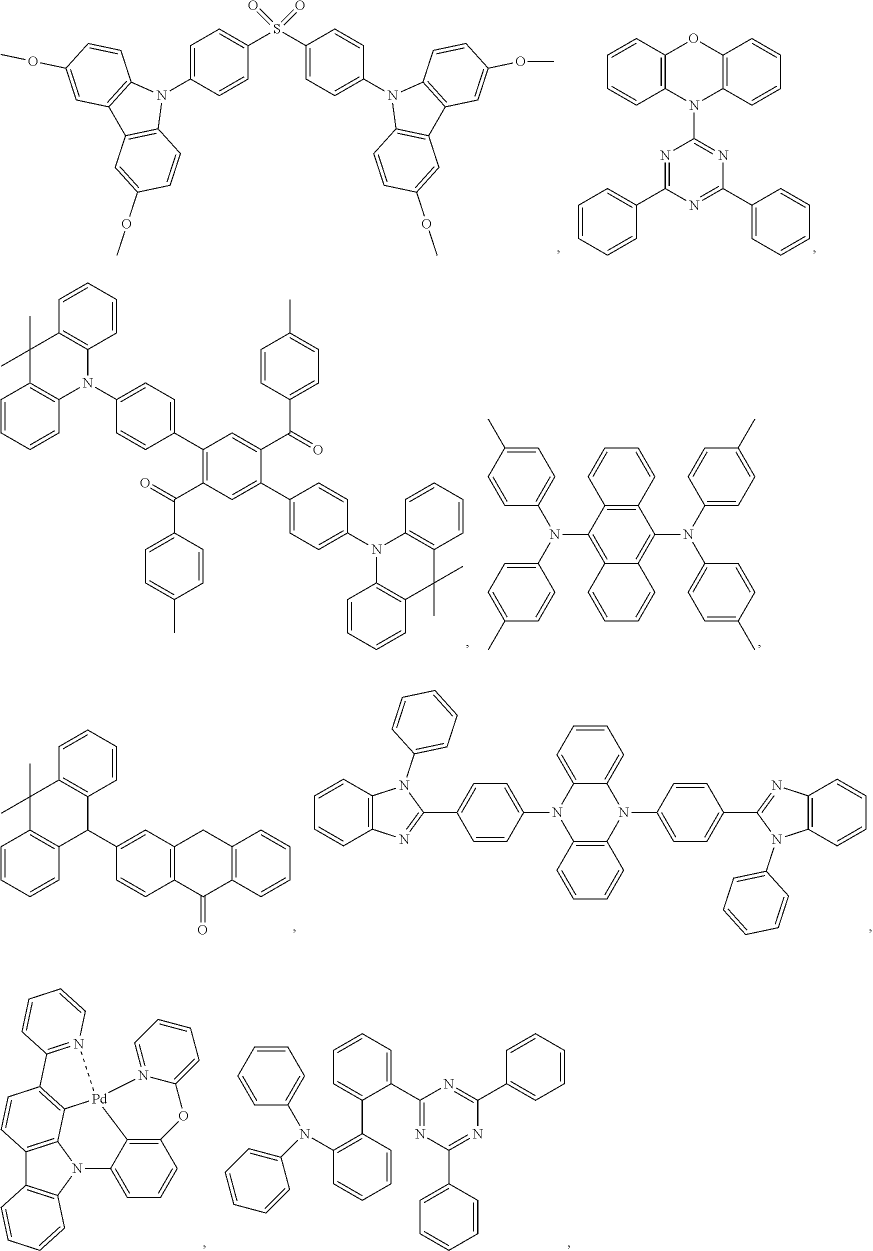

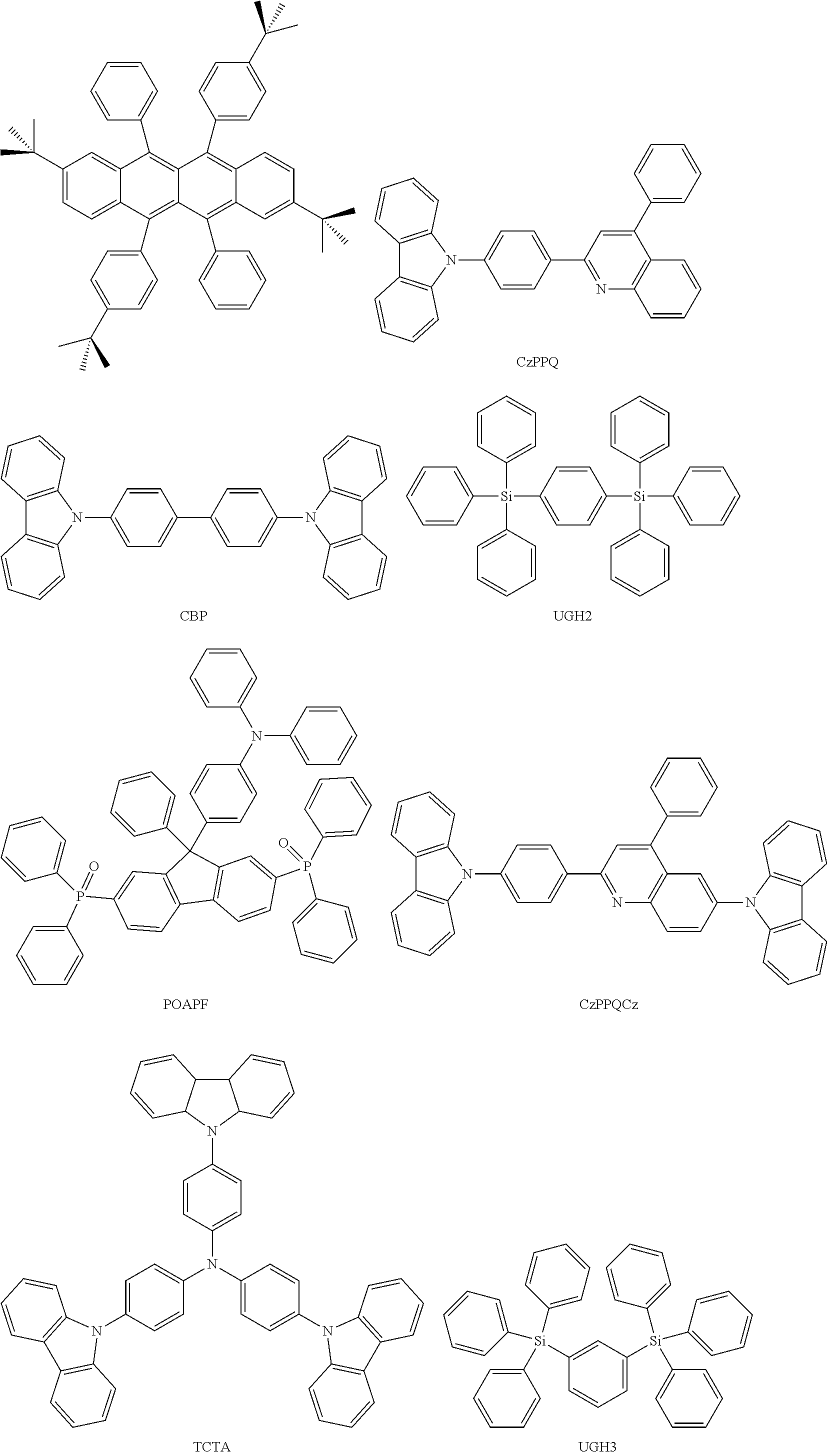

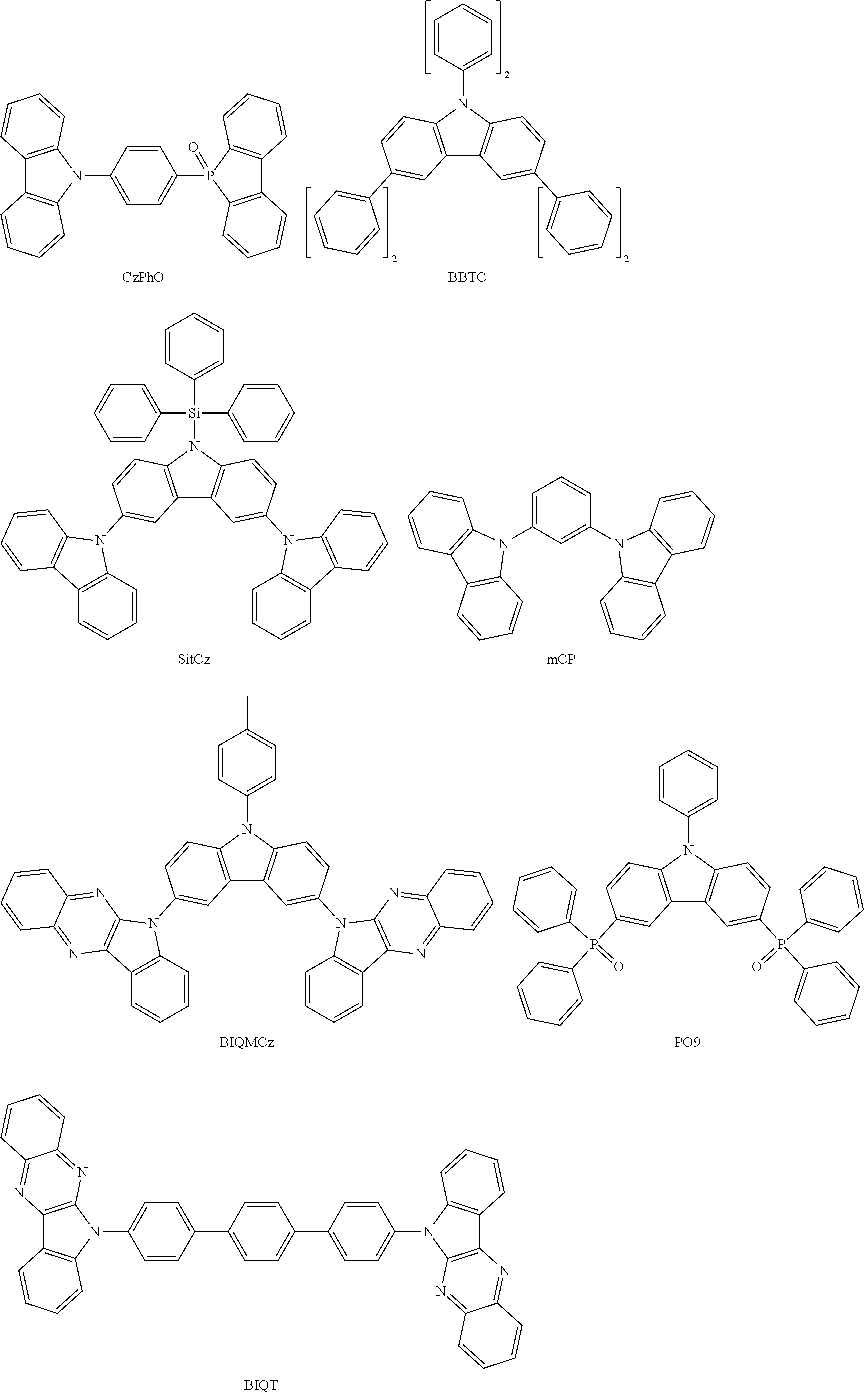

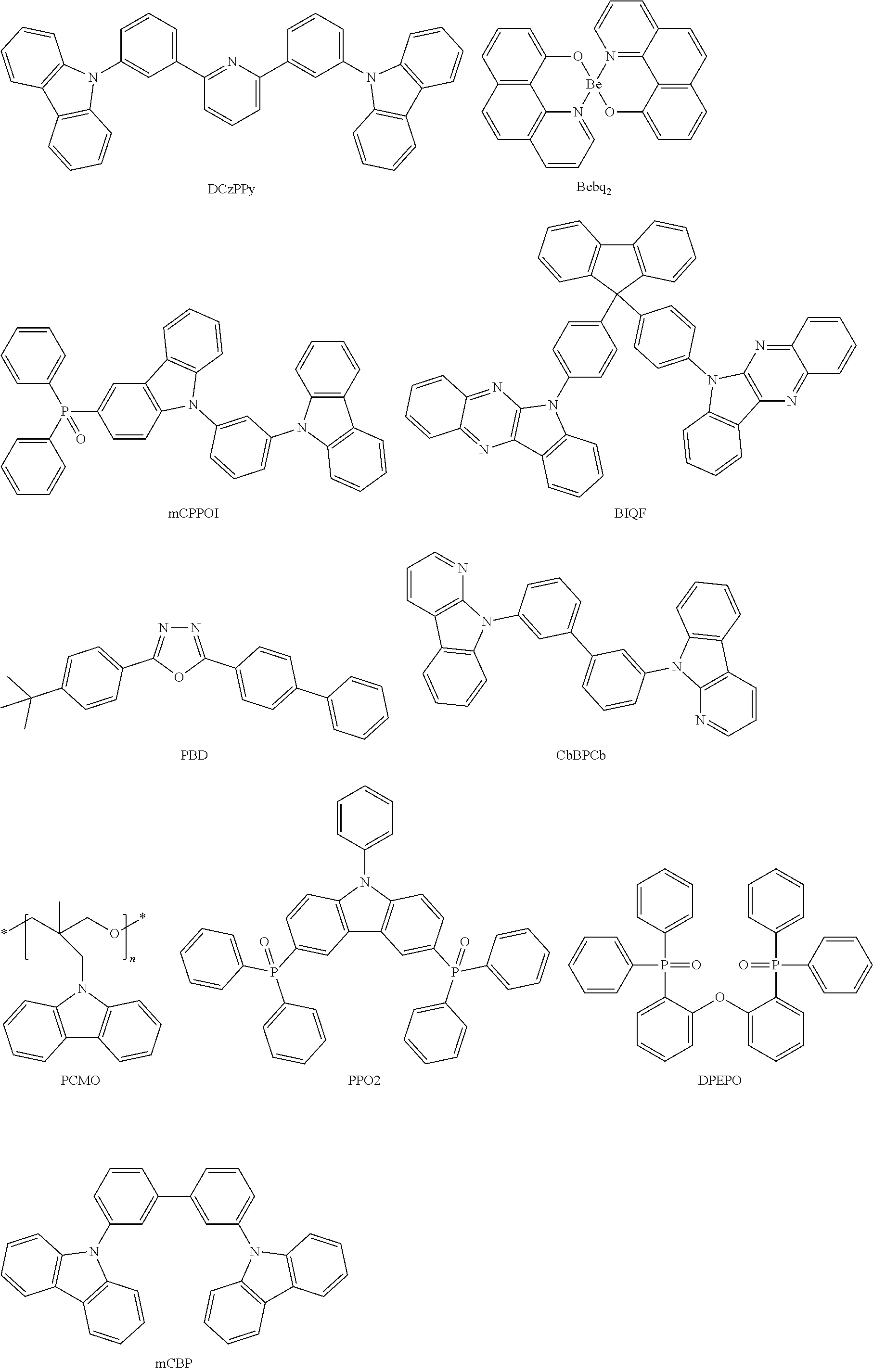

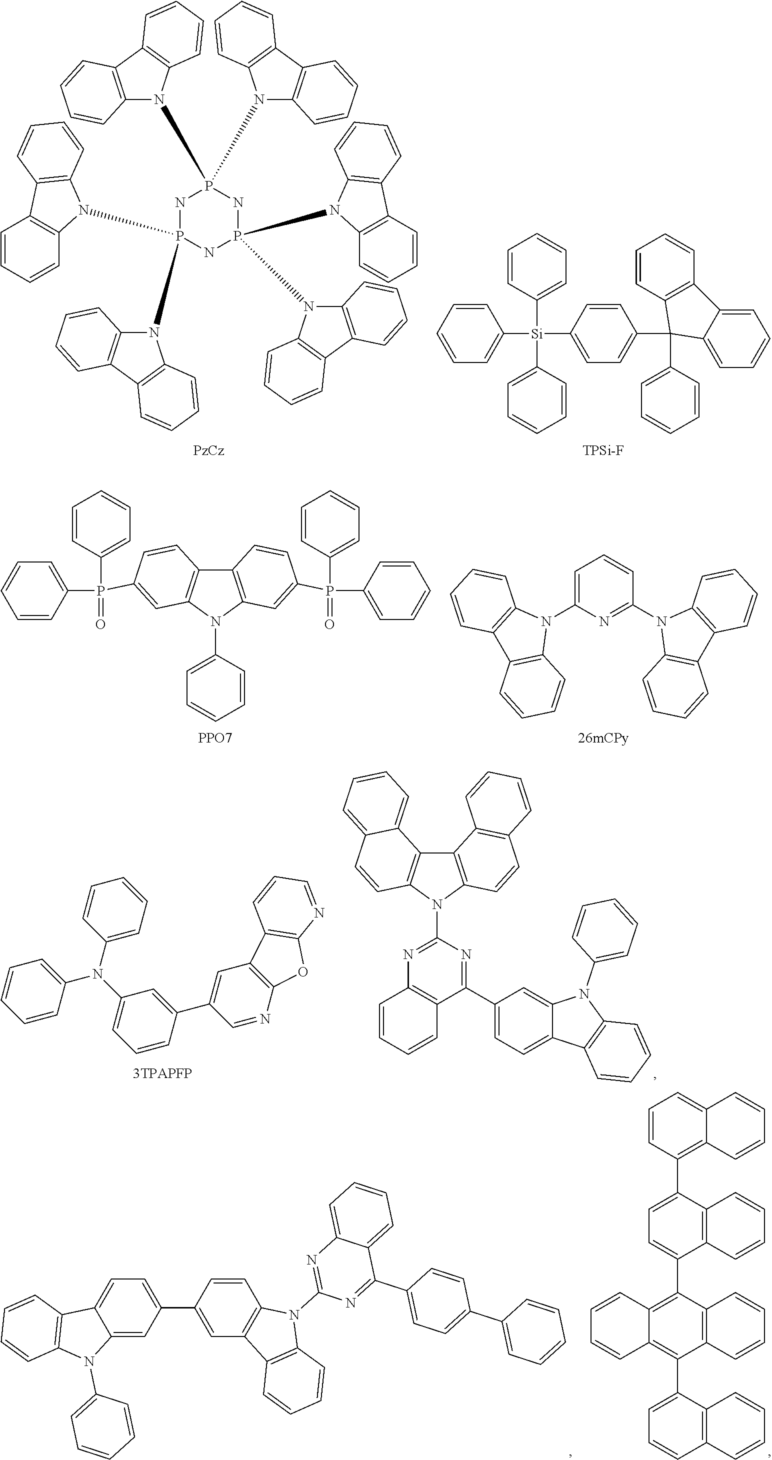

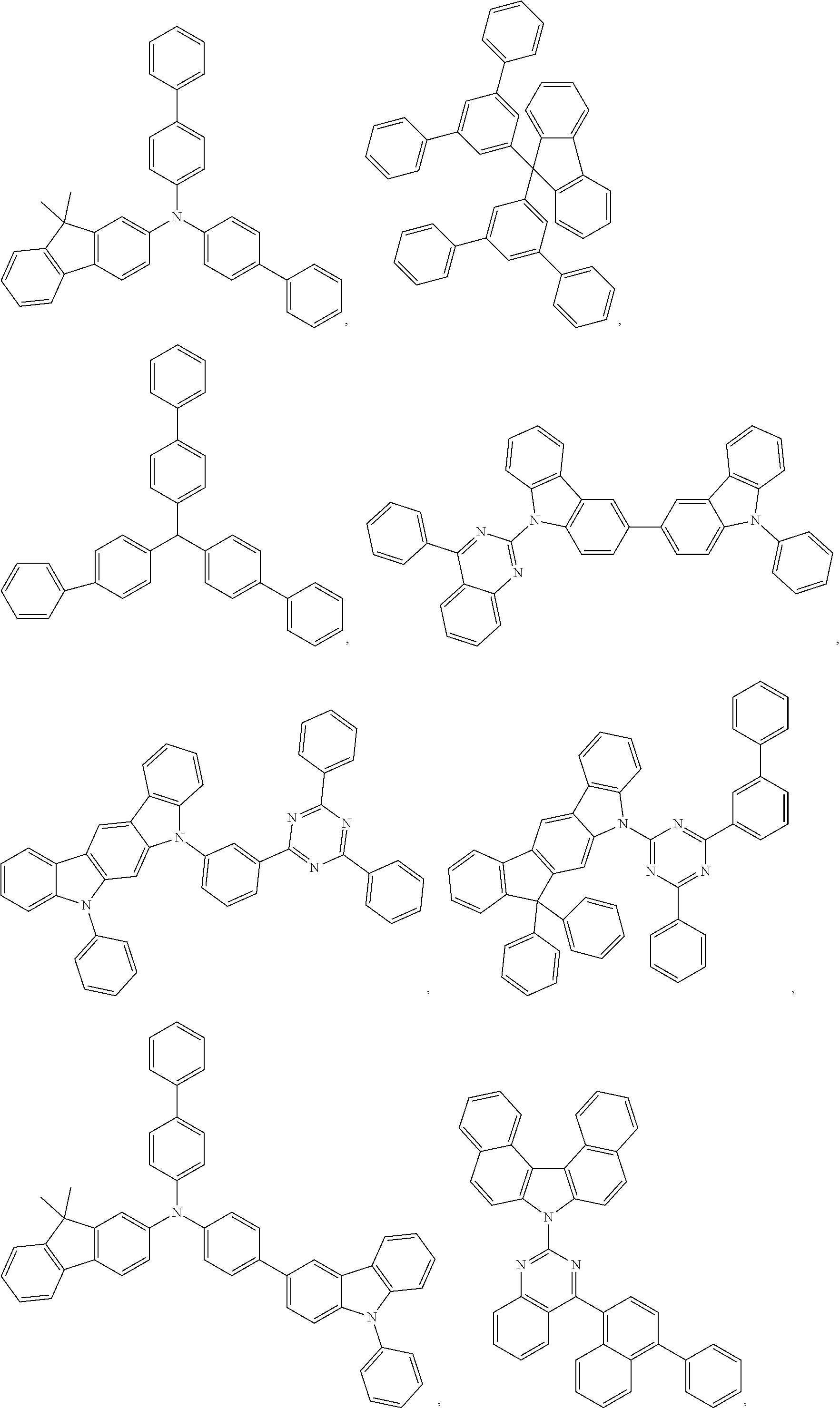

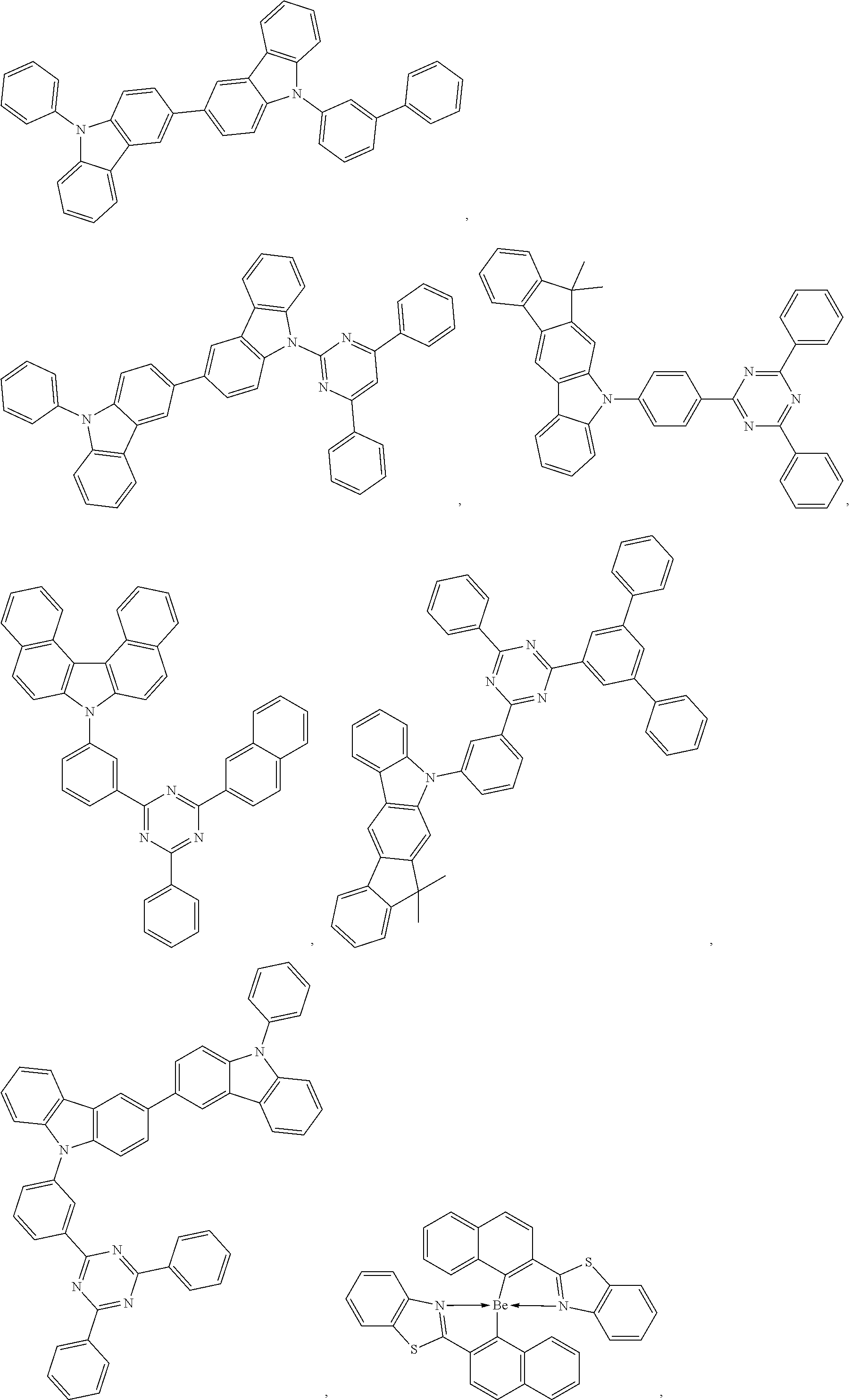

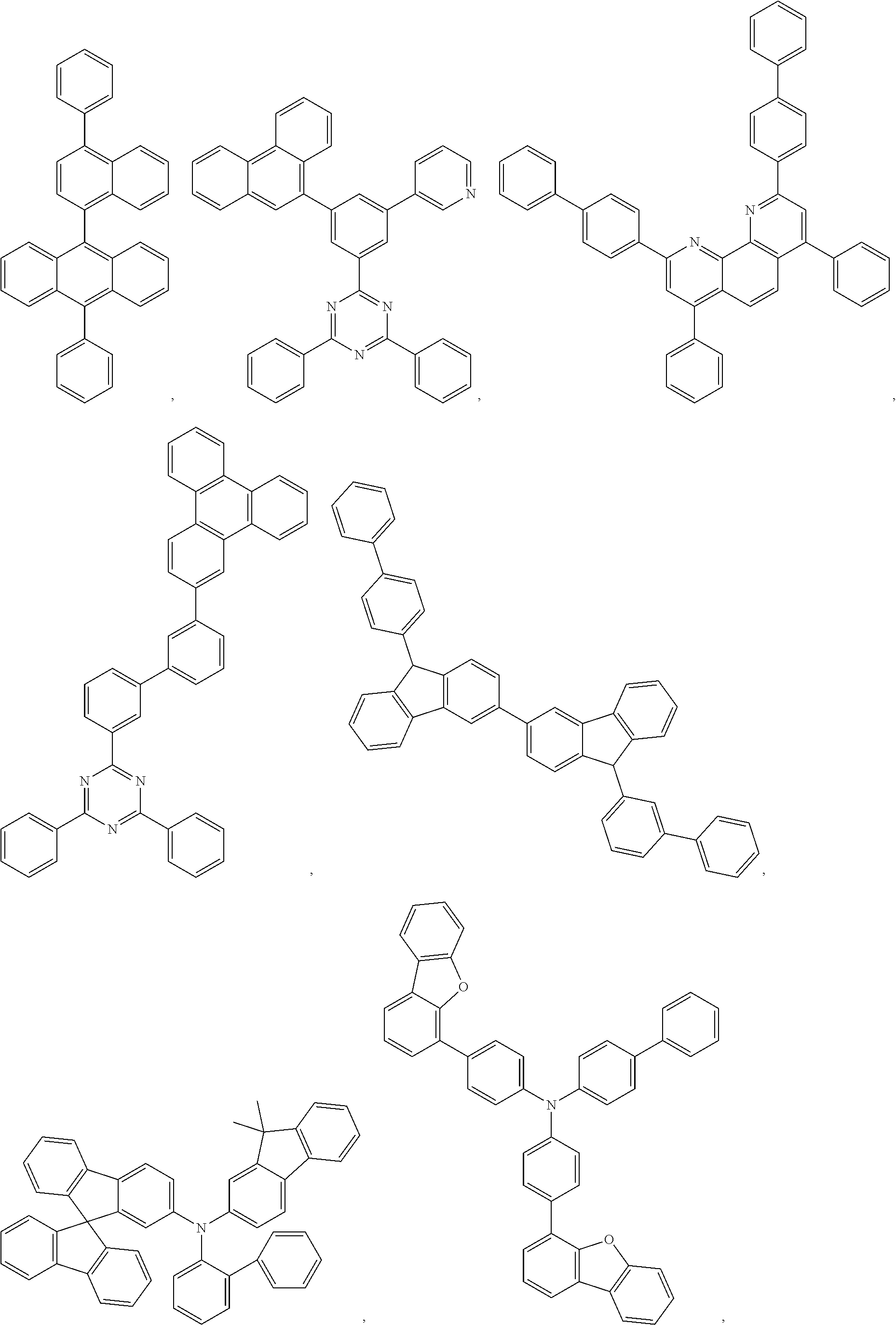

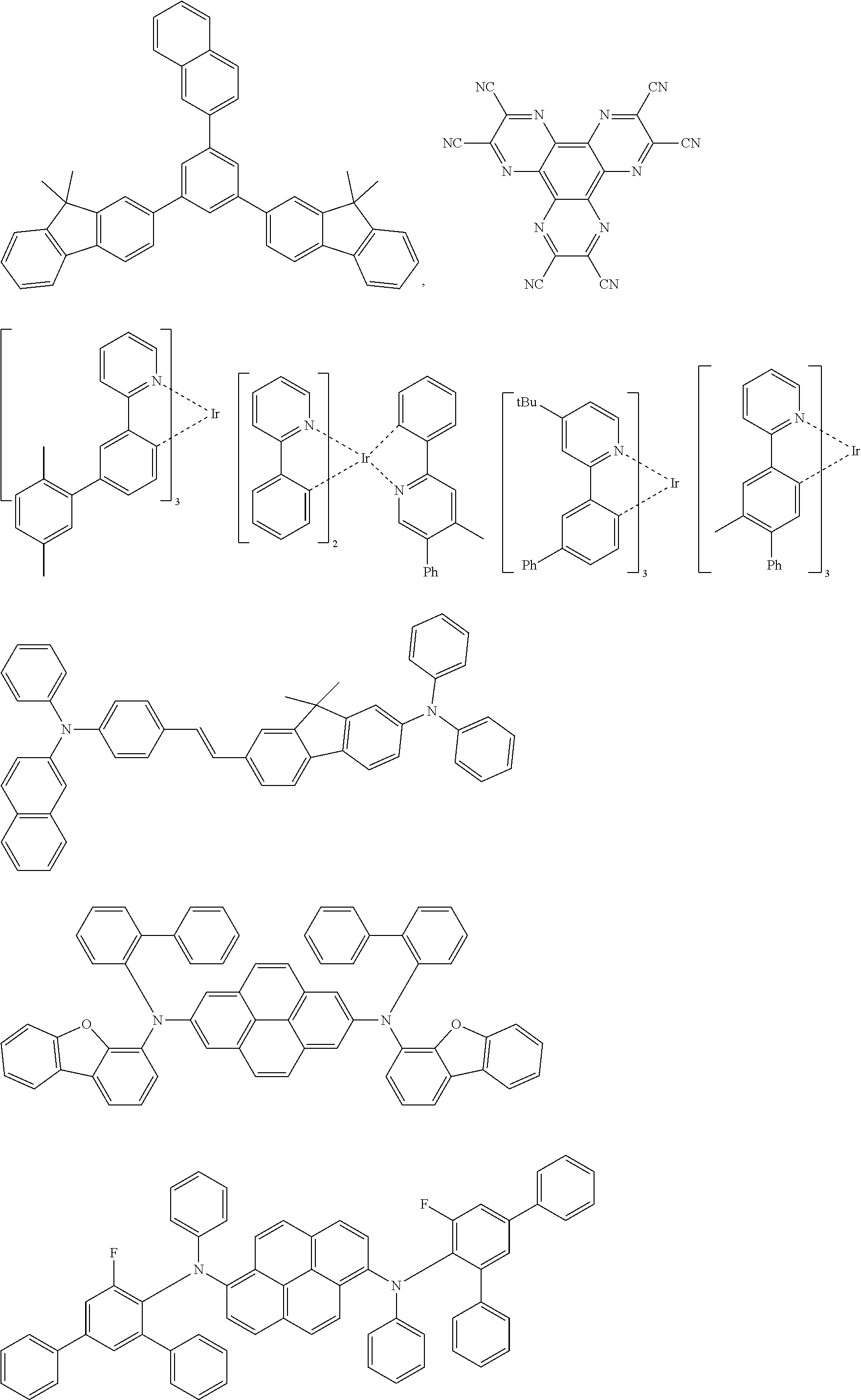

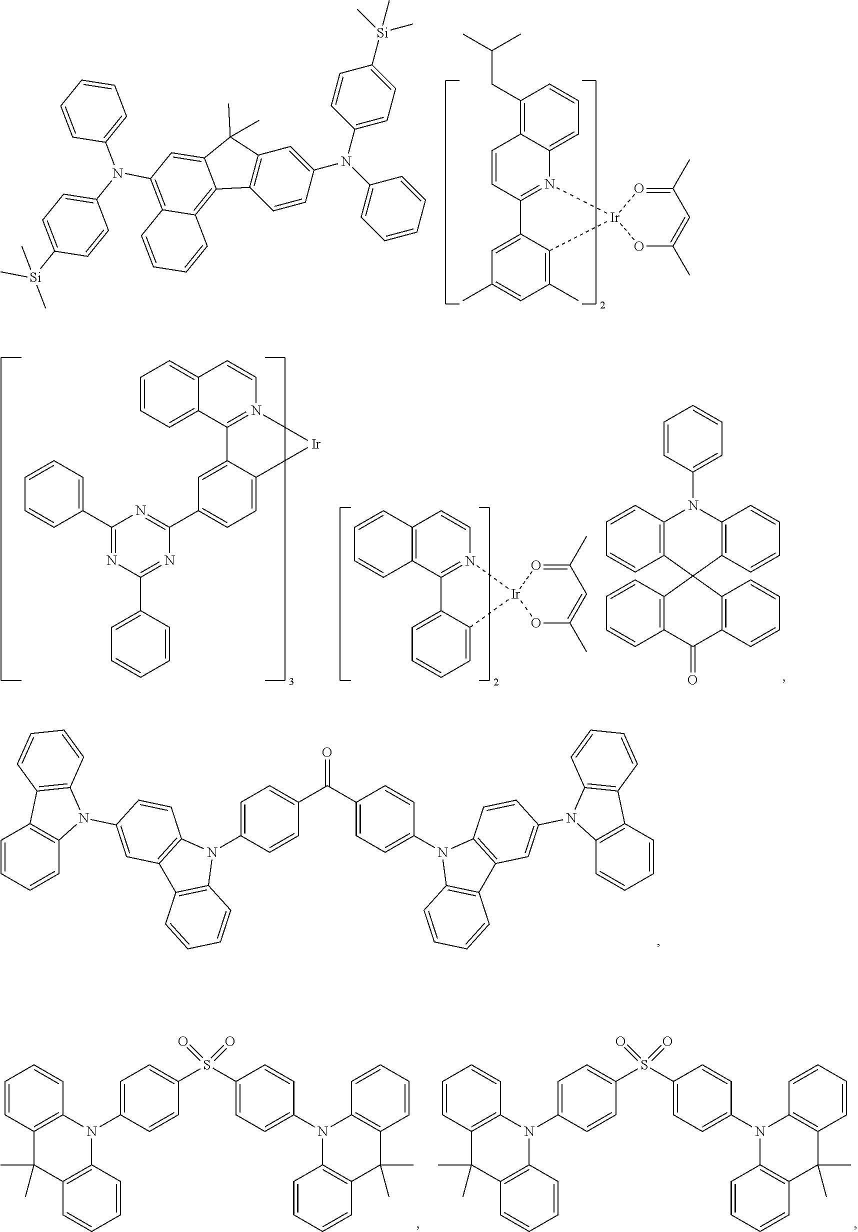

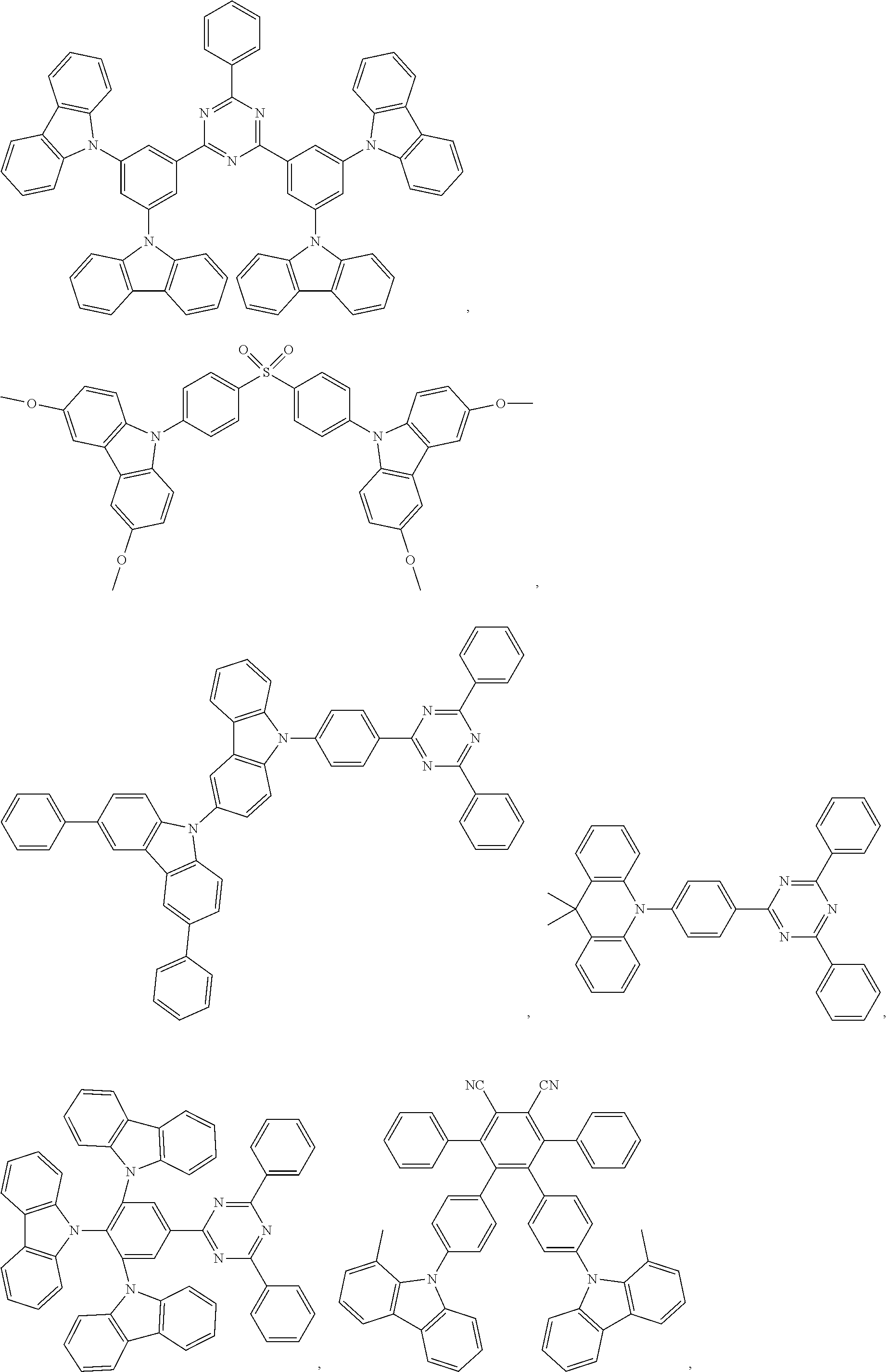

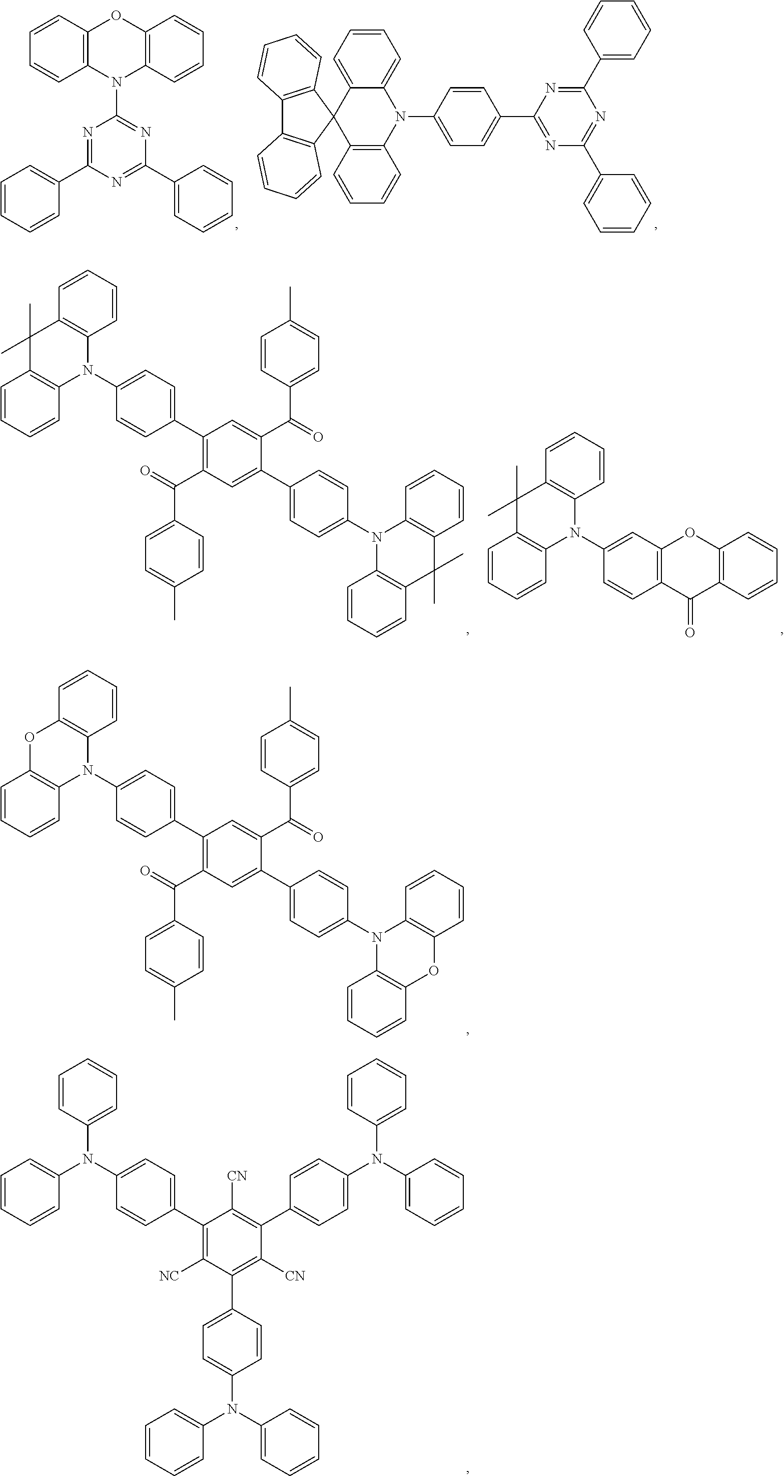

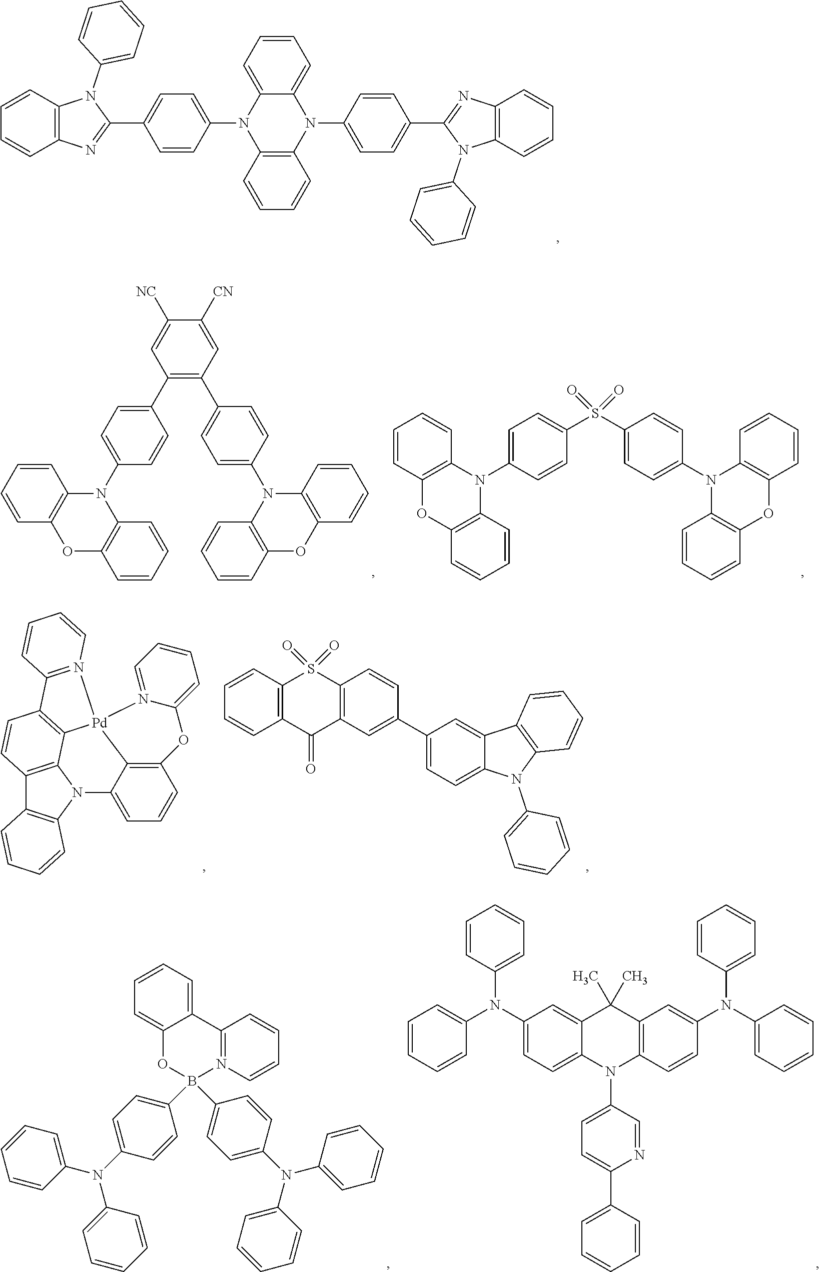

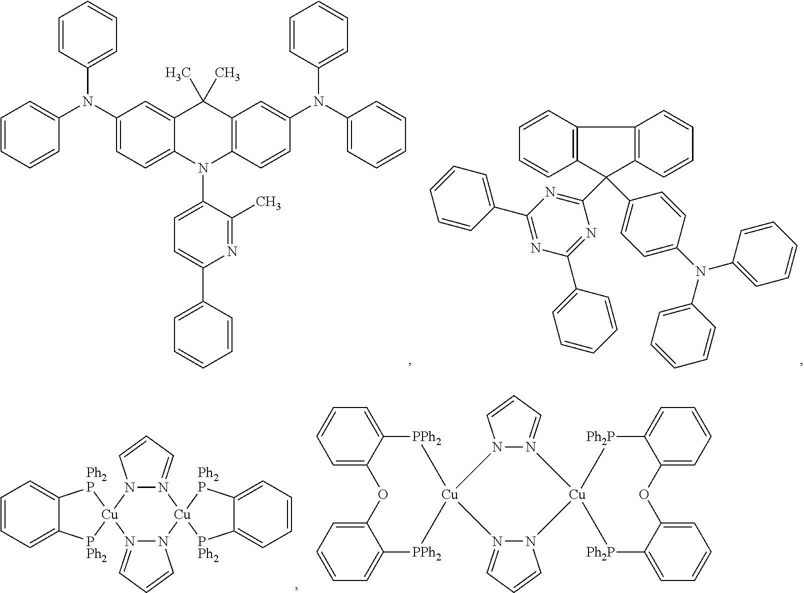

Exemplary electroactive moieties include the hole transport material (HTM), 4,4′-cyclohexylidenebis[N,N-bis(4-methylphenyl)benzenamine] (TAPC) or N,N′-Di(1-naphthyl)-N,N′-diphenyl-(1,1′-biphenyl)-4,4′-diamine (NPD) or bathophenanthroline. Combinations of the foregoing electroactive moieties may also be used if desired.

The electroactive moiety is present in the composition in an amount of 10 to 90 vol %, preferably 30 to 70 vol % and more preferably 40 to 60 vol %, based on a total weight of the composition.

In one embodiment, in one method of manufacturing the composition, a substrate that is to be coated with the composition is placed in an oven or in a reactor. The oven or reactor is capable of being under vacuum. Vapors of the polymer precursor and of the electroactive moiety are simultaneously introduced into the oven or reactor and condense on the substrate to form the composition. In an embodiment, the substrate may be cooled to a temperature below room temperature (23° C.), preferably less than 15° C., and more preferably less than 10° C. The vapors that form the polymer may be obtained directly by heating a monomer (or a polymer precursor) or by depolymerizing an existing polymer to form smaller polymeric moieties (e.g., monomers, dimers, trimers, tetramers, pentamers, and so on, that are capable of existing in vapor form at the selected processing temperature).

As noted above, the manufactured composition exists in the form of a co-continuous network of the polymer and the electroactive moiety. The polymer network provides thermal stability to the composition and increases the increases the thermal stability of a variety of transport layers by greater than or equal to 50° C. without compromising their electrical transport. In some other cases, the presence of the polymer can stabilize the morphology and increase operating temperature, but does appear to adversely affect electrical transport. In some other embodiments, the presence of the polymer can improve electrical transport even at room temperature.

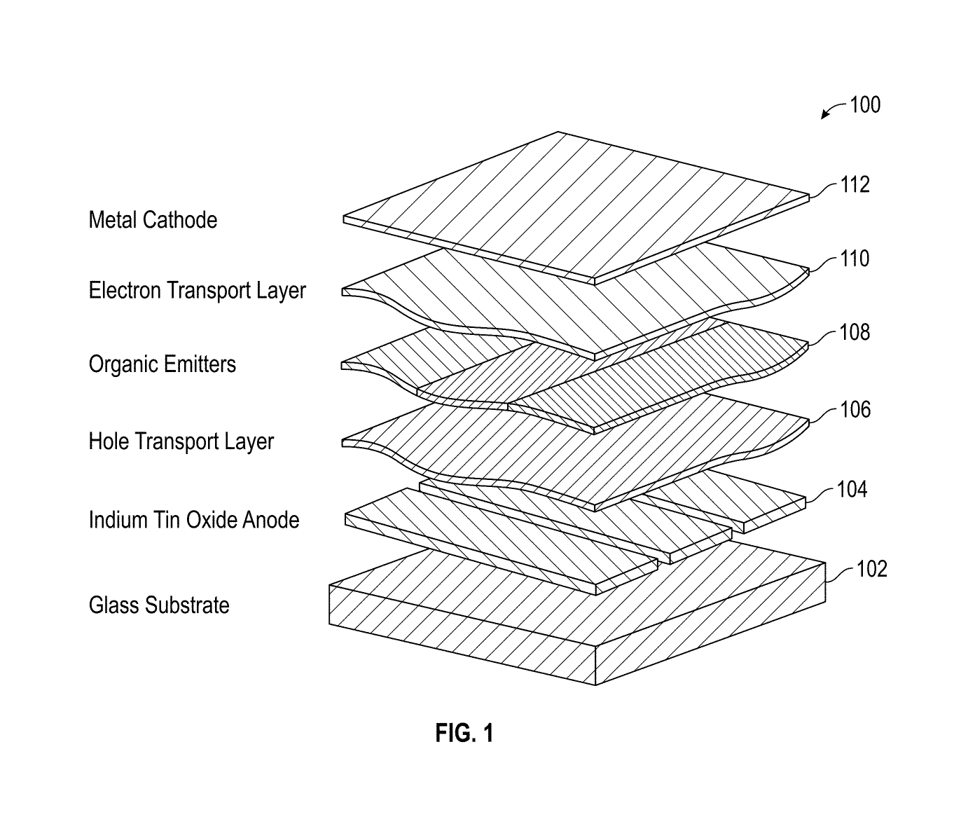

In an embodiment, the composition may be fabricated into an article. In another embodiment, the article disclosed herein may be used as an emissive layer in a display. FIG. 1 depicts one exemplary embodiment of a display 100. In an embodiment, a display device comprises a substrate 102 upon which is disposed in sequence an anode 104, a hole transport layer 106, an emission layer 108, an electron transport layer 110 and a cathode 112. The hole transport layer 106, the emission layer 108 and the electron transport layer 110 may each comprise an interpenetrating polymer network and an electroactive moiety. For example, the hole transport layer 106 may comprise a hole transport electroactive moiety and a polymer that exist in the form of the disclosed interpenetrating network. Similarly, the emission layer 108 may comprise an emissive electroactive moiety and a polymer that exists in the form of the disclosed interpenetrating network. The electron transport layer 110 may comprise an electron transport electroactive moiety and a polymer that exists in the form of the disclosed interpenetrating network.

In an embodiment, the display devices may be a pixelated light emitting diode that can emit light of single color (a single wavelength) or of a plurality of colors (light having different wavelengths). For example, it can emit white light or can emit red, green and blue light that can be combined to produce white light. The article may be used to produce light in the entire visible light spectrum.

In an embodiment, the display device may be a micro organic light emitting diode or a white organic light emitting diode (WOLED). The WOLED may have a color conversion layer. The color conversion layer may comprise periodical nanospheres that help extract the confined light in the device and also increase the effective light path to achieve more efficient color conversion. The composition disclosed herein may be used in flat displays, curved displays, transparent displays and in multilayer displays. The composition disclosed herein may be used as lighting such as, for example, white lighting, red lighting, conformal light coatings, color adjusting lighting, lighting for sign boards, or the like.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

The invention is exemplified by the following non-limiting examples.

### EXAMPLES

### Example 1

This example was conducted to demonstrate the formation of the composition comprising the electroactive moiety and the polymeric interpenetrating network. The polymeric interpenetrating network comprises polytetrafluoroethylene (commercially available as TEFLON AF) while the electroactive material comprises an OLED hole transport material (HTM)—4,4′-cyclohexylidenebis[N,N-bis(4-methylphenyl)benzenamine] (TAPC).

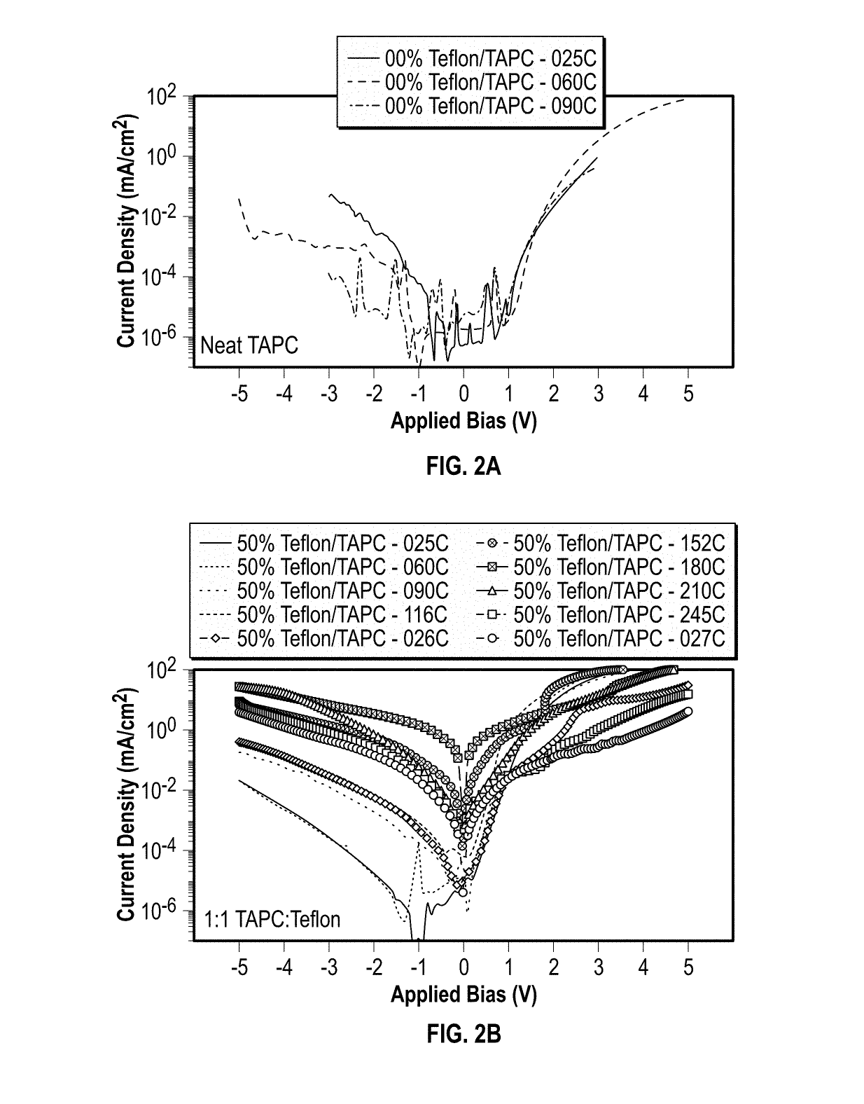

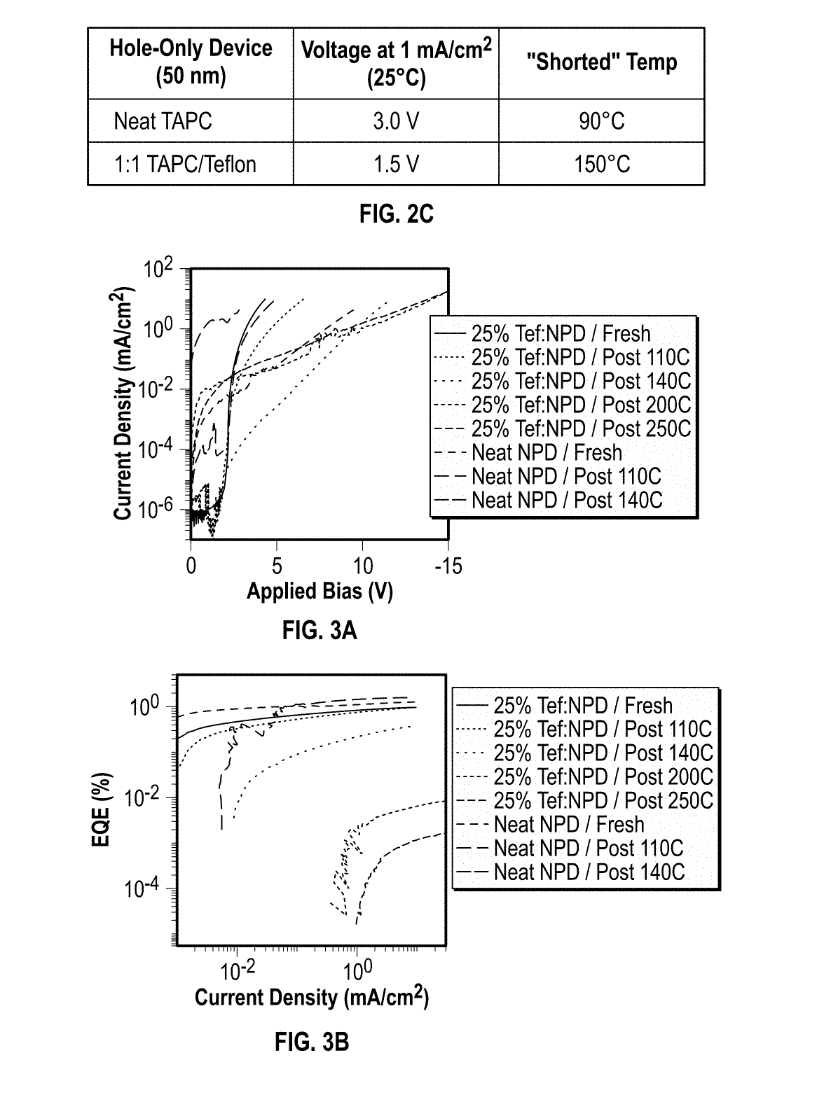

The FIG. 2 details the result of TEFLON AF addition to hole-only devices based on the hole transport material (HTM), 4,4′-cyclohexylidenebis[N,N-bis(4-methylphenyl)benzenamine] (TAPC). The hole-only device structure consists of an indium-tin-oxide (ITO) substrate (having a thickness of about 100 nanometers) upon which is disposed the hole transport material 4,4′-cyclohexylidenebis[N,N-bis(4-methylphenyl)benzenamine]. An aluminum electrode having a thickness of 50 nanometers contacts the opposing surface of the hole transport material.

The ITO substrates are cleaned with solvents and ultraviolet-ozone treatment. The HTM in the control device is neat TAPC with 50 nm thickness whereas that in the TEFLON-blended device is half TAPC and half TEFLON by volume with a total thickness of 74 nm.

The TEFLON AF 1600 is co-evaporated with TAPC from separate molybdenum boats in a thermal evaporator at a pressure of approximately 10⁻⁶ Torr. The relative evaporation rates of each material are selected to yield a final film with approximately 50 vol % TEFLON in TAPC and the net deposition rate is approximately 5 Å/second with a substrate temperature of approximately 0° C. FIGS. 2A and 2B respectively display the current density-voltage (J-V) characteristics of the neat TAPC and TEFLON:TAPC devices at various temperatures on a hot plate, tested in air.

The table in FIG. 2C summarizes the key comparison points between the two device types. In addition to the approximate 60° C. increase in thermal stability for the TEFLON:TAPC devices (based on the temperature at which they shorted), the drive voltage required for the TEFLON:TAPC devices to reach J=1 mA/cm² at room temperature is roughly half that of their neat TAPC counterparts, despite the fact that they are nearly 50% thicker. This may reflect improved hole injection, improved bulk transport, or both. The potential for improved injection may be related to a reduced hole injection barrier due to electronic interaction between the TEFLON and ITO.

This is an example of the criteria outlined above. Without being limited to theory, believe TEFLON works for hole transport materials because its chain fragments have HOMO energies that are lower than the HOMO of the hole transport molecules so that they do not form hole trap states. However, when used with electron transporting materials, the LUMO of TEFLON fragments may be lower than that of the electron transporting material, which leads to the introduction of electron trap states and the consequent deterioration of electrical transport.

### Example 2

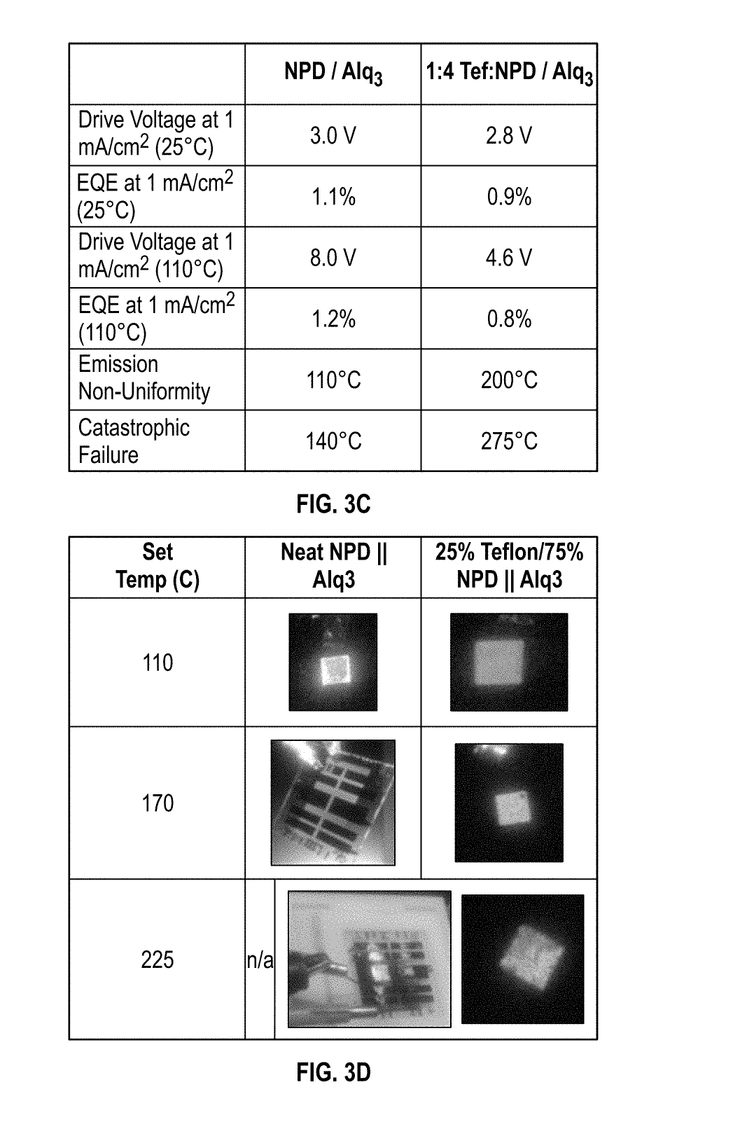

The second example consists of a canonical bilayer N,N′-di(1-naphthyl)-N,N′-diphenyl-(1,1′-biphenyl)-4,4′-diamine (NPD)/Tris(8-hydroxyquinolinato)aluminum (Alq3) OLED. The device structure consists of ITO (100 nm)/HTM (60 nm)/Alq3 (60 nm)/Al (50 nm), where the HTM is either neat NPD or NPD co-evaporated with 25 vol % TEFLON AF 1600. The net TEFLON:NPD deposition rate in this case is 5 Å/second and the substrate temperature is approximately 0° C. FIGS. 3A and 3B respectively display the J-V characteristics and external quantum efficiency (EQE) measured for these devices after successively heating them to different temperatures on a hot plate and then measuring them back at ambient temperature.

The table in the FIG. 3C summarizes the key comparison points between the neat and TEFLON-blended devices together with their visual appearance in the photograph matrix on the right-hand side (i.e., FIG. 3D).

Similar to the hole-only devices of FIG. 2, the bilayer OLEDs featuring TEFLON have a lower drive voltage at J=1 mA/cm² than the neat NPD/Alq₃ controls. The EQE at J=1 mA/cm² is slightly lower for the TEFLON-based OLEDs (˜0.9% vs. 1.1% for the control devices), though this small difference may simply reflect a slight change in optical outcoupling due to the different HTM thickness and refractive index or reduced charge balance due to improved hole injection/transport.

Significant visual changes in light emission (non-uniformity) and a large voltage increase are observed for the control OLEDs after raising their temperature to 110° C. whereas the TEFLON-based OLEDs maintain their emission uniformity and feature a much smaller voltage increase at this temperature. The control OLEDs fail catastrophically at 140° C. (i.e. they no longer emit any light) whereas the TEFLON-based OLEDs continue to operate above 250° C.

### Example 3

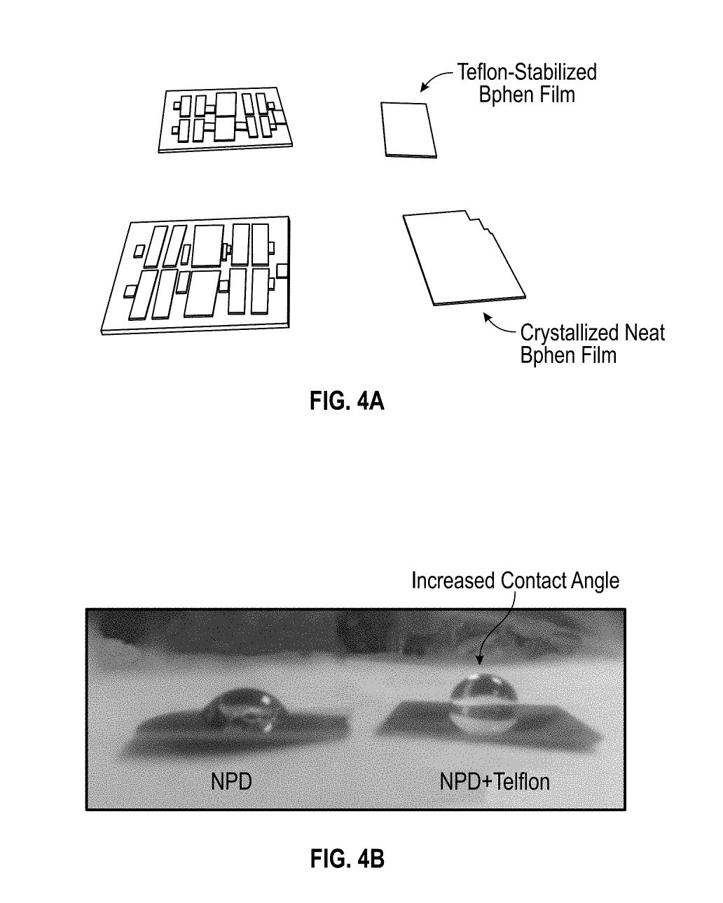

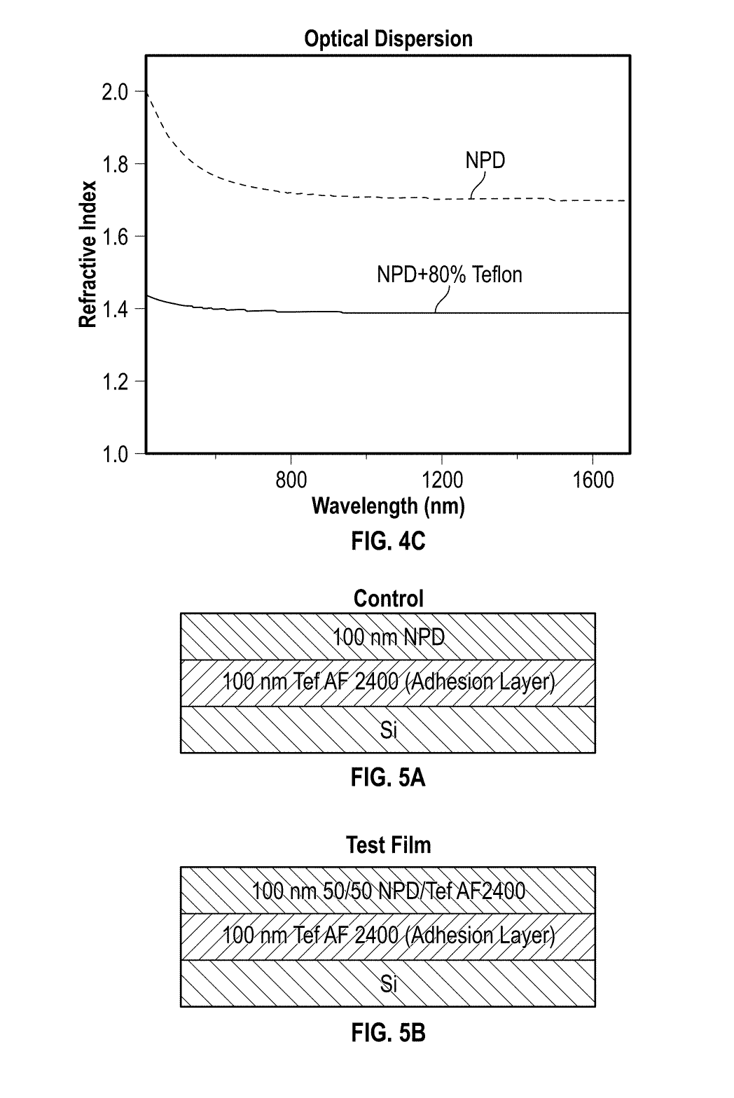

This example was conducted to demonstrate the improved morphological stability of compositions that contain interpenetrating networks of the OLED and the polymer. FIG. 4A below shows the improved morphological stability of TEFLON-blended OLED materials stored over extended time periods. In this case, the OLED electron-transport material bathophenanthroline (BPhen) is co-evaporated with 50% TEFLON onto a silicon substrate. Neat BPhen films display strong crystallization after several days of storage whereas the TEFLON-based Bphen films show no degradation. In addition to morphological stability, the presence of TEFLON in NPD increases its water contact angle as shown in FIG. 4B and also decreases its refractive index as shown in FIG. 4C.

### Example 4

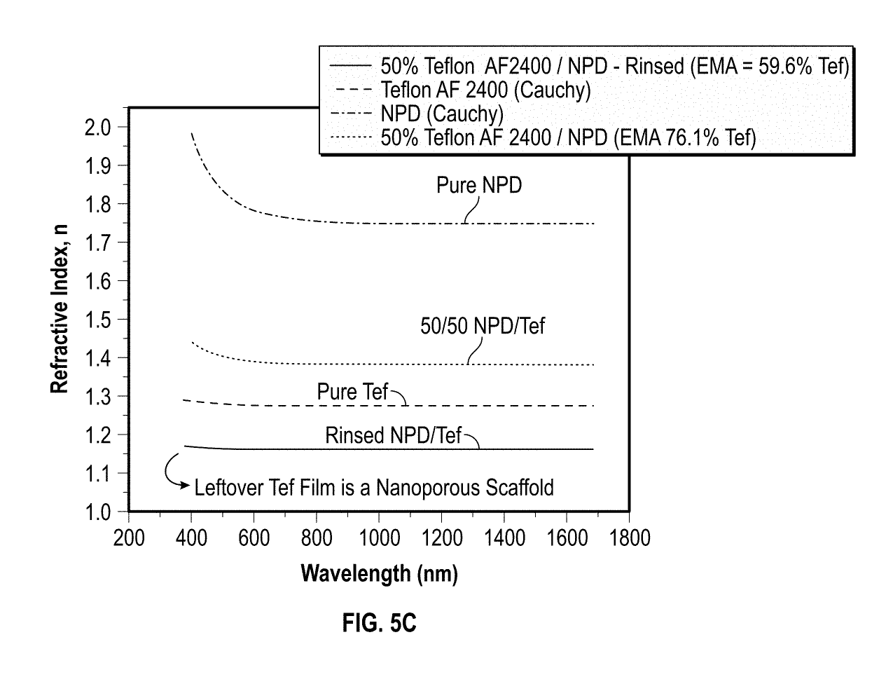

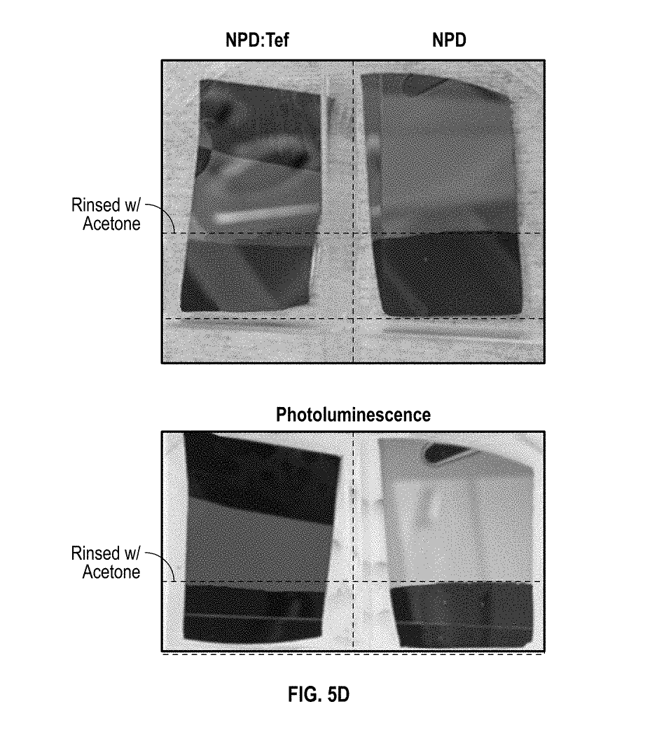

The FIG. 5 provides support for the morphology-stabilizing network of TEFLON chains that is hypothesized to underlie the stability improvements described above. In this experiment, a 1:1 co-evaporated film of TEFLON AF2400 and NPD is measured via ellipsometry before and after washing the film with acetone, which readily dissolves NPD but does not dissolve TEFLON. The ellipsometry results indicate that the refractive index of the original 1:1 film is well described by an effective medium approximation blend of pure TEFLON and NPD. However, in the acetone-washed film, the resulting film has a significantly lower refractive index than pure TEFLON, indicating that the NPD has been removed and a matrix of TEFLON/air remains. The elimination of the NPD is also supported by the photographs on the right, which demonstrate the elimination of NPD photoluminescence from the rinse region of the film. The effective medium approximation in this case indicates a large fraction of void space in the remaining TEFLON film, which must be on the nanoscale because the films remain specular.

FIG. 5A depicts the test structure for the control sample that contains only the electroactive moiety. FIG. 5B depicts the test structure for a sample that contains the electroactive moiety and the polymer. FIG. 5C is a graph that shows the refractive index for the a) pure NPD, b) the NPD/TEFLON AF composition, c) the pure TEFLON AF and d) the TEFLON AF sample after removing the NPD. FIG. 5D is a photomicrograph that shows the pure NPD sample and d) the NPD/TEFLON AF sample before and after removal of the NPD.

These results strongly suggest that a nanoporous TEFLON framework exists in the co-evaporated film to begin with and is subsequently exposed by selectively dissolving out the NPD.

What is claimed is:

1. A composition comprising:
a co-continuous interpenetrating network of an organic polymer and a electroactive moiety;
where the organic polymer is operative to depolymerize at a temperature of 50 to 500° C. and to repolymerize on a surface in the presence of the electroactive moiety; and where the electroactive moiety is an organic semiconductor that does not react with a repolymerized polymer.

2. The composition of claim 1, where the organic polymer is fluorinated polymer and the electroactive moiety is a non-fluorinated electroactive moiety that is operative to transport an electrical charge and to undergo luminescence.

3. The composition of claim 1, where the organic polymer comprises a thermoplastic polymer; a thermosetting polymer or a blend thereof.

4. The composition of claim 1, where the organic polymer has the molecular structure: 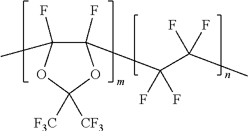
where m and n are the number of repeat units and each have independent values of 10 to 5,000.

5. The composition of claim 1, where the electroactive moiety comprises a substituted or unsubstituted carbazole compound, a substituted or unsubstituted thiophene compound, a substituted or unsubstituted sulfonyl compound, a substituted or unsubstituted phosphino compound, a substituted or unsubstituted phosphoryl compound, a substituted or unsubstituted nitrile compound, a substituted or unsubstituted fluorene compound, a substituted or unsubstituted triazine compound, a substituted or unsubstituted phenoxazine compound, a substituted or unsubstituted quinazoline compound, a substituted or unsubstituted pyridine compound, a substituted or unsubstituted benzenamine, a substituted or unsubstituted amine, a metallo-organic complex, or a combination thereof.

6. The composition of claim 1, where the electroactive moiety comprises a host material, a hole transport material, a hole injection material, an emitter material, an electron transport material, or a combination thereof.

7. The composition of claim 1, where the electroactive moiety comprises 4,4′-cyclohexylidenebis[N,N-bis(4-methylphenyl)benzenamine], N,N′-di(1-naphthyl)-N,N′-diphenyl-(1,1′-biphenyl)-4,4′-diamine, bathophenanthroline, or a combination thereof.

8. An article comprising the composition of claim 1.

9. A method comprising:
co-evaporating a polymeric precursor and an electroactive moiety onto a substrate;
condensing the polymeric precursor and an electroactive moiety on the substrate; and
polymerizing the polymeric precursor to form a co-continuous interpenetrating network of an organic polymer and an electroactive moiety; where the electroactive moiety is defined as a chemical functional group which is capable of transporting an electrical charge.

10. The method of claim 9, further comprising depolymerizing an existing polymer to form the polymeric precursor.

11. The method of claim 10, where the existing polymer is an amorphous fluoropolymer.
